(19) United States
(12) Patent Application Publication
(10) Pub. No.: US 2026/0093180 A1
(43) Pub. Date: Apr. 2, 2026

(54) METHOD FOR MANUFACTURING SEMICONDUCTOR SUBSTRATE AND COMPOSITION FOR FILM FORMATION

(71) Applicant: JSR CORPORATION, Tokyo (JP)

(72) Inventors: Kengo HIRASAWA, Tokyo (JP); Kazuya TAKADA, Tokyo (JP); Yuki OZAKI, Tokyo (JP); Hironori KIMATA, Tokyo (JP); Ryuichi SERIZAWA, Tokyo (JP)

(73) Assignee: JSR CORPORATION, Tokyo (JP)

(21) Appl. No.: 19/044,924

(22) Filed: Feb. 4, 2025

Related U.S. Application Data
(63) Continuation-in-part of application No. PCT/JP2023/025616, filed on Jul. 11, 2023.

(30) Foreign Application Priority Data
Aug. 12, 2022 (JP) 2022-128827

(51) Int. Cl. G03F 7/09; H10P 76/20

(52) U.S. Cl. CPC G03F 7/094; H10P 76/20

(57) ABSTRACT

A method for manufacturing a semiconductor substrate includes applying a composition for film formation to a substrate. The composition includes: a metal compound; an aromatic compound including an aromatic hydrocarbon ring structure and a partial structure represented by formula (1); and a solvent. The aromatic hydrocarbon ring structure has 6 or more carbon atoms. X is a group represented by formula (i) (ii), (iii) or (iv). R¹ is a hydrogen atom or a monovalent organic group having 1 to 20 carbon atoms, and R² is a monovalent organic group having 1 to 20 carbon atoms. R³ is a hydrogen atom or a monovalent organic group having 1 to 20 carbon atoms, and R⁴ is a monovalent organic group having 1 to 20 carbon atoms. R⁵ is a monovalent organic group having 1 to 20 carbon atoms. R⁶ is a monovalent organic group having 1 to 20 carbon atoms.

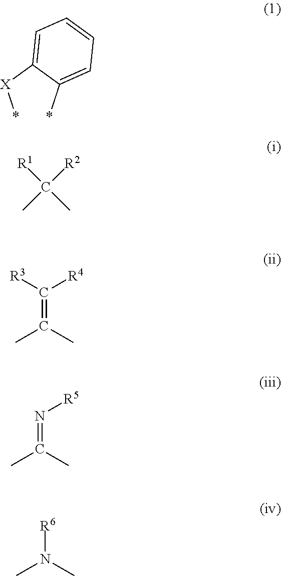

### CROSS-REFERENCE TO RELATED APPLICATIONS

The present application is a continuation-in-part application of International Patent Application No. PCT/JP2023/025616 filed Jul. 11, 2023, which claims priority to Japanese Patent Application No. 2022-128827 filed Aug. 12, 2022. The contents of these applications are incorporated herein by reference in their entirety.

### BACKGROUND OF THE DISCLOSURE

### Technical Field

The present disclosure relates to a method for manufacturing a semiconductor substrate and a composition for film formation.

### Background Art

A semiconductor device is produced using, for example, a multilayer resist process in which a resist pattern is formed by exposing to light and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the substrate to obtain a patterned substrate (see JP-A-2004-177668).

In recent years, metal hardmask compositions have been proposed as a resist underlayer film (see JP-A-2013-185155).

### SUMMARY

According to an aspect of the present disclosure, a method for manufacturing a semiconductor substrate, includes applying a composition for film formation to a substrate. The composition for film formation includes: a metal compound; an aromatic compound including an aromatic hydrocarbon ring structure and a partial structure represented by formula (1); and a solvent. The aromatic hydrocarbon ring structure has 6 or more carbon atoms.

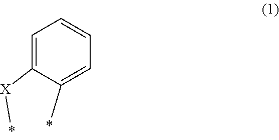

In the formula (1), X is a group represented by formula (i), (ii), (iii) or (iv); and * are bonding sites with two adjacent carbon atoms constituting the aromatic hydrocarbon ring structure.

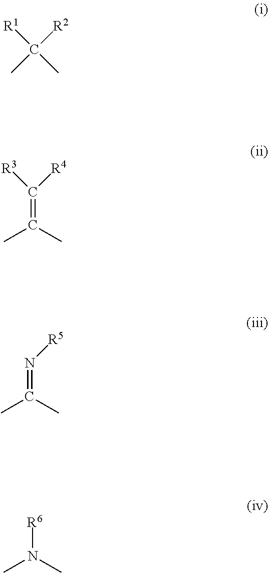

In the formula (i), R¹ is a hydrogen atom or a monovalent organic group having 1 to 20 carbon atoms, and R² is a monovalent organic group having 1 to 20 carbon atoms. In the formula (ii), R³ is a hydrogen atom or a monovalent organic group having 1 to 20 carbon atoms, and R⁴ is a monovalent organic group having 1 to 20 carbon atoms. In the formula (iii), R⁵ is a monovalent organic group having 1 to 20 carbon atoms. In the formula (iv), R⁶ is a monovalent organic group having 1 to 20 carbon atoms.

According to another aspect of the present disclosure, a composition for film formation includes: a metal compound; an aromatic compound including an aromatic hydrocarbon ring structure and a partial structure represented by formula (1); and a solvent. The aromatic hydrocarbon ring structure has 6 or more carbon atoms.

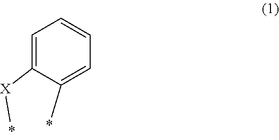

In the formula (1), X is a group represented by formula (i), (ii), (iii) or (iv); and * are bonding sites with two adjacent carbon atoms constituting the aromatic hydrocarbon ring structure.

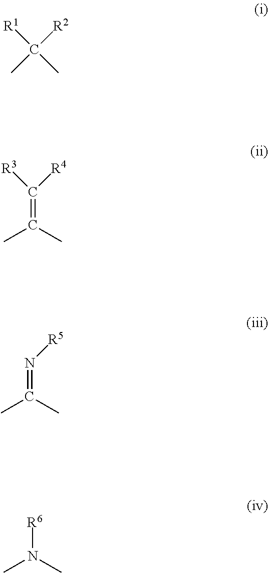

In the formula (i), R¹ is a hydrogen atom or a monovalent organic group having 1 to 20 carbon atoms, and R² is a monovalent organic group having 1 to 20 carbon atoms. In the formula (ii), R³ is a hydrogen atom or a monovalent organic group having 1 to 20 carbon atoms, and R⁴ is a monovalent organic group having 1 to 20 carbon atoms. In the formula (iii), R⁵ is a monovalent organic group having 1 to 20 carbon atoms. In the formula (iv), R⁶ is a monovalent organic group having 1 to 20 carbon atoms.

### BRIEF DESCRIPTION OF THE DRAWINGS

FIG. 1 is an electron micrograph taken when a trench pattern is embedded using the composition of Example 1-1; and

FIG. 2 is an electron micrograph taken when a trench pattern is embedded using the composition of Comparative Example 1-1.

### DESCRIPTION OF THE EMBODIMENTS

Recently, substrates on which a pattern such as a trench or a hole is formed are often used, and metal hardmask compositions are required to be superior in etching resistance and to be able to form a metal hardmask capable of sufficiently embedding a pattern of a substrate.

By the method for manufacturing a semiconductor substrate of the embodiments of the present disclosure, since a resist underlayer film superior in etching resistance and embeddability is formed, a well patterned semiconductor substrate can be obtained. When the composition for film formation of the embodiments of the present disclosure is used, a film superior in etching resistance and embeddability can be formed. Therefore, these can suitably be used for, for example, manufacturing semiconductor devices expected to be further microfabricated in the future.

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

### <<Method for Manufacturing Semiconductor Substrate>>

The method for manufacturing a semiconductor substrate includes a step of applying a composition for film formation to a substrate (hereinafter also referred to as an “applying step”). Furthermore, the method for manufacturing a semiconductor substrate preferably includes: a step of forming a resist pattern directly or indirectly on the resist underlayer film formed by the applying step (hereinafter also referred to as a “resist pattern forming step”); and a step of forming a pattern on the film by etching using the resist pattern as a mask (hereinafter also referred to as an “etching step”).

If necessary, the method for manufacturing a semiconductor substrate may further include, before the resist pattern forming step, forming an organic underlayer film directly or indirectly on the substrate having a resist underlayer film formed in the applying step (hereinafter also referred to as an “organic underlayer film forming step).

If necessary, the method for manufacturing a semiconductor substrate may further include, before the resist pattern forming step, forming a silicon-containing film directly or indirectly on the substrate having a resist underlayer film formed in the applying step (hereinafter also referred to as a “silicon-containing film forming step).

First, a composition for film formation to be used in the method for manufacturing a semiconductor substrate is described. After that, description will be made to respective steps in the case where the method includes the resist pattern forming step and the etching step, which are preferable steps, and an organic underlayer film forming step and a silicon-containing film forming step, which are optional steps.

### <Composition for Film Formation>

The composition for film formation (this composition is hereinafter also referred to as “composition”) includes a compound [A], a compound [B], and a solvent [C]. The composition may further include other optional components as long as the effect of the present invention is not impaired. A trench or a hole sized several tens of nanometers may not be sufficiently embedded only with a metal compound and a solvent as a metal hardmask composition. In the composition, due to the inclusion of the compound [B] together with the compound [A], superior embeddability and etching resistance can be exhibited.

### [Compound [A]]

The compound [A] is a compound including a metal atom and an oxygen atom. Examples of the metal atom constituting the compound [A] include metal atoms of Groups 3 to 16 of the periodic table (excluding silicon atom). The compound [A] may have one kind or two or more kinds of metal atom.

Examples of Group 3 metal atom include scandium, yttrium, lanthanum, and cerium;
examples of Group 4 metal atom include titanium, zirconium, and hafnium;
examples of Group 5 metal atom include vanadium, niobium, and tantalum;
examples of Group 6 metal atom include chromium, molybdenum, and tungsten;
examples of Group 7 metal atom include manganese and rhenium;
examples of Group 8 metal atom include iron, ruthenium, and osmium;
examples of Group 9 metal atom include cobalt, rhodium, and iridium;
examples of Group 10 metal atom include nickel, palladium, and platinum;
examples of Group 11 metal atom include copper, silver, and gold;
examples of Group 12 metal atom include zinc, cadmium, and mercury;
examples of Group 13 metal atom include aluminum, gallium, and indium;
examples of Group 14 metal atom include germanium, tin, and lead;
examples of Group 15 metal atom include antimony and bismuth; and
examples of Group 16 metal atom include tellurium.

As the metal atom constituting the compound [A], metal atoms of Group 3 to Group 16 are preferable, metal atoms of Group 4 to Group 14 are more preferable, metal atoms of Group 4, Group 5, and Group 14 are still more preferable, and metal atoms of Group 4 are particularly preferable. Specifically, titanium, zirconium, hafnium, tantalum, tungsten, tin, or a combination thereof is more preferable.

As the component (hereinafter also referred to as “compound [x]”) other than the metal atom constituting the compound [A], an organic acid (hereinafter also referred to as “organic acid [a]”), a hydroxy acid ester, a β-diketone, an α,α-dicarboxylic acid ester, and an amine compound are preferable. Herein, the “organic acid” refers to any organic compound that exhibits acidity, and the “organic compound” refers to any compound having at least one carbon atom.

Examples of the organic acid [a] include carboxylic acids, sulfonic acids, sulfinic acids, organic phosphinic acids, organic phosphonic acids, phenols, enols, thiols, acid imides, oximes, and sulfonamides.

Examples of the carboxylic acids include monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid, and shikimic acid; dicarboxylic acids such as oxalic acid, malonic acid, maleic acid, methylmalonic acid, fumaric acid, adipic acid, sebacic acid, phthalic acid, and tartaric acid; and carboxylic acids having three or more carboxy groups such as citric acid.

Examples of the sulfonic acids include benzenesulfonic acid and p-toluenesulfonic acid.

Examples of the sulfinic acids include benzenesulfinic acid and p-toluenesulfinic acid.

Examples of the organic phosphinic acids include diethylphosphinic acid, methylphenylphosphinic acid, and diphenylphosphinic acid.

Examples of the organic phosphonic acids include methylphosphonic acid, ethylphosphonic acid, t-butylphosphonic acid, cyclohexylphosphonic acid, and phenylphosphonic acid.

Examples of the phenols include monohydric phenols such as phenol, cresol, 2,6-xylenol, and naphthol;
dihydric phenols such as catechol, resorcinol, hydroquinone, and 1,2-naphthalenediol; and
trihydric or higher phenols such as pyrogallol and 2,3,6-naphthalenetriol.

Examples of the enols include 2-hydroxy-3-methyl-2-butene and 3-hydroxy-4-methyl-3-hexene.

Examples of the thiols include mercaptoethanol and mercaptopropanol.

Examples of the acid imides include carboxylic acid imides such as maleimide and succinimide, and sulfonic acid imides such as di(trifluoromethanesulfonic acid) imide and di(pentafluoroethanesulfonic acid) imide.

Examples of the oximes include aldoximes such as benzaldoxime and salicylaldoxime, and ketoximes such as diethylketoxime, methylethylketoxime, and cyclohexanone oxime.

Examples of the sulfonamides include methylsulfonamide, ethylsulfonamide, benzenesulfonamide, and toluenesulfonamide.

As the organic acid [a], carboxylic acids are preferable, monocarboxylic acids are more preferable, and methacrylic acid and benzoic acid are still more preferable.

Examples of the hydroxy acid esters include glycolic acid esters, lactic acid esters, 2-hydroxycyclohexane-1-carboxylic acid esters, and salicylic acid esters.

Examples of the β-diketones include 2,4-pentanedione, 3-methyl-2,4-pentanedione, and 3-ethyl-2,4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the amine compounds include diethanolamine and triethanolamine.

As the compound [A], metal compounds composed of a metal atom and an organic acid [a] are preferable, metal compounds composed of a Group 4, Group 5 or Group 14 metal atom and a carboxylic acid are more preferable, and metal compounds composed of titanium, zirconium, hafnium, tantalum, tungsten or tin and methacrylic acid or benzoic acid are still more preferable.

The compound [A] may include one or two or more of the metal compound.

The compound [A] may include one or two or more of the organic acid [a].

The lower limit of the content ratio of the compound [A] accounting for in all components contained in the composition is preferably 2% by mass, more preferably 4% by mass, and still more preferably 6% by mass. The upper limit of the content ratio is preferably 30% by mass, more preferably 20% by mass, and still more preferably 15% by mass.

### [Method for Synthesizing Compound [A]]

The compound [A] can be synthesized by, for example, a method of performing a hydrolysis-condensation reaction using a metal-containing compound [b], a method of performing a ligand substitution reaction using a metal-containing compound [b], or the like. Herein, the “hydrolysis-condensation reaction” refers to a reaction in which the hydrolyzable group of the metal-containing compound [b] is hydrolyzed to be converted into —OH, and the resulting two —OH groups are dehydration-condensed to form —O—.

(Metal-Containing Compound [b])

The metal-containing compound [b] is a metal compound (b1) having a hydrolyzable group, a hydrolysate of a metal compound (b1) having a hydrolyzable group, a hydrolysis-condensate of a metal compound (b1) having a hydrolyzable group, or a combination thereof. The metal compound (b1) may be used singly or two or more thereof may be used in combination.

Examples of the hydrolyzable group include a halogen atom, an alkoxy group, and an acyloxy group.

Examples of the halogen atom include a fluorine atom, a chlorine atom, a bromine atom, and an iodine atom.

Examples of the alkoxy group include a methoxy group, an ethoxy group, a n-propoxy group, an isopropoxy group, and a n-butoxy group.

Examples of the acyloxy group include an acetoxy group, an ethylyloxy group, a propionyloxy group, a butyryloxy group, a t-butyryloxy group, a t-amylyloxy group, an n-hexanecarbonyloxy group, and an n-octanecarbonyloxy group.

As the hydrolyzable group, an alkoxy group and an acyloxy group are preferable, and an isopropoxy group and an acetoxy group are more preferable.

When the metal-containing compound [b] is a hydrolysis-condensate of a metal compound (b1), the hydrolysis-condensate of the metal compound (b1) may be a hydrolysis-condensate of the metal compound (b1) having a hydrolyzable group and a compound containing a metalloid atom as long as the effect of the present invention is not impaired. That is, the hydrolysis-condensate of the metal compound (b1) may contain a metalloid atom as long as the effect of the present invention is not impaired. Examples of the metalloid atom include silicon, boron, germanium, antimony, and tellurium. The content of the metalloid atom in the hydrolysis-condensate of the metal compound (b1) is usually less than 50 atom % based on the total of the metal atom and the metalloid atom in the hydrolysis-condensate. The upper limit of the content of the metalloid atom is preferably 30 atom %, more preferably 10 atom % based on the total of the metal atom and the metalloid atom in the hydrolysis-condensate.

Examples of the metal compound (b1) include a compound represented by formula (a) (hereinafter also referred to as “compound [m]”).

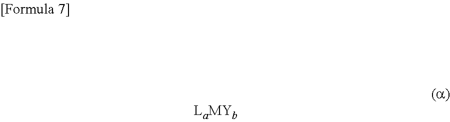

In the formula (α), M is a metal atom. L is a ligand. a is an integer of 0 to 2. When a is 2, a plurality of L's are the same or different. Y is a hydrolyzable group selected from among a halogen atom, an alkoxy group, and an acyloxy group. b is an integer of 2 to 6. The plurality of Y's may be the same or different. Note that L is a ligand that does not correspond to Y.

Examples of the metal atom represented by M include metal atoms the same as those disclosed as examples of the metal atom constituting the metal compound contained in the compound [A].

Examples of the ligand represented by L include a monodentate ligand and a multidentate ligand.

Examples of the monodentate ligand include a hydroxo ligand, a carboxy ligand, an amide ligand, and ammonia.

Examples of the amide ligand include an unsubstituted amide ligand (NH₂), a methylamide ligand (NHMe), a dimethylamide ligand (NMe₂), a diethylamide ligand (NEt₂), and a dipropylamide ligand (NPr₂).

Examples of the multidentate ligand include hydroxy acid esters, β-diketones, β-ketoesters, β-dicarboxylic acid esters, hydrocarbons having a n bond, and diphosphines.

Examples of the hydroxy acid esters include glycolic acid esters, lactic acid esters, 2-hydroxycyclohexane-1-carboxylic acid esters, and salicylic acid esters.

Examples of the β-diketones include 2,4-pentanedione, 3-methyl-2,4-pentanedione, and 3-ethyl-2,4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the β-dicarboxylic acid esters include malonic diesters, α-alkyl-substituted malonic diesters, α-cycloalkyl-substituted malonic diesters, and α-aryl-substituted malonic diesters.

Examples of the hydrocarbons having a π bond include
chain olefins such as ethylene and propylene;
cyclic olefins such as cyclopentene, cyclohexene, and norbornene;
chain dienes such as butadiene and isoprene;
cyclic dienes such as cyclopentadiene, methylcyclopentadiene, pentamethylcyclopentadiene, cyclohexadiene, and norbornadiene; and
aromatic hydrocarbons such as benzene, toluene, xylene, hexamethylbenzene, naphthalene, and indene.

Examples of the diphosphines include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, and 1,1′-bis(diphenylphosphino)ferrocene.

Examples of the halogen atom represented by Y include a fluorine atom, a chlorine atom, a bromine atom, and an iodine atom.

Examples of the alkoxy group represented by Y include a methoxy group, an ethoxy group, a propoxy group, and a butoxy group.

Examples of the acyloxy group represented by Y include an acetoxy group, an ethylyloxy group, a butyryloxy group, a t-butyryloxy group, a t-amylyloxy group, an n-hexanecarbonyloxy group, and an n-octanecarbonyloxy group.

As Y, an alkoxy group and an acyloxy group are preferable, and an isopropoxy group and an acetoxy group are more preferable.

As b, 3 and 4 are preferable, and 4 is more preferable.

As the metal-containing compound [b], metal alkoxides subjected to neither hydrolysis nor hydrolysis-condensation and metal acyloxides subjected to neither hydrolysis nor hydrolysis-condensation are preferable.

Examples of the metal-containing compound [b] include zirconium tetra-n-butoxide, zirconium tetra-n-propoxide, zirconium tetraisopropoxide, hafnium tetraethoxide, indium triisopropoxide, hafnium tetraisopropoxide, hafnium tetra-n-propoxide, hafnium tetra-n-butoxide, tantalum pentaethoxide, tantalum penta-n-butoxide, tungsten pentamethoxide, tungsten penta-n-butoxide, tungsten hexaethoxide, tungsten hexa-n-butoxide, iron chloride, zinc diisopropoxide, zinc acetate dihydrate, tetrabutyl orthotitanate, titanium tetra-n-butoxide, titanium tetra-n-propoxide, zirconium di-n-butoxide bis(2,4-pentanedionate), titanium tri-n-butoxide stearate, bis(cyclopentadienyl)hafnium dichloride, bis(cyclopentadienyl)tungsten dichloride, diacetato[(S)-(−)-2,2′-bis(diphenylphosphino)-1,1′-binaphthyl]ruthenium, dichloro[ethylenebis(diphenylphosphine)]cobalt, titanium butoxide oligomer, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono(acetylacetonato)titanium, tri-isopropoxymono(acetylacetonato)titanium, triethoxymono(acetylacetonato)zirconium, tri-n-propoxymono(acetylacetonato)zirconium, tri-isopropoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, tin tetraisopropoxide, tin tetra-n-butoxide, lanthanum oxide, and yttrium oxide.

Among them, metal alkoxides and metal acyloxides are preferable, metal alkoxides are more preferable, and alkoxides of titanium, zirconium, hafnium, tantalum, tungsten, and tin are still more preferable.

When an organic acid is used for the synthesis of the compound [A], the lower limit of the amount of the organic acid used is preferably 1 mol, more preferably 2 mol, per mole of the metal-containing compound [b]. On the other hand, the upper limit of the amount of the organic acid used is preferably 6 mol, more preferably 5 mol, per mole of the metal-containing compound [b].

In the synthesis reaction of the compound [A], in addition to the metal compound (b1) and the organic acid [a], a compound capable of serving as a multidentate ligand represented by L in the compound of the formula (α), a compound capable of serving as a bridging ligand, or the like may be added. Examples of the compound capable of serving as a bridging ligand include compounds having a plurality of hydroxy groups, isocyanate groups, amino groups, ester groups, or amide groups.

Examples of the method of performing the hydrolysis-condensation reaction using the metal-containing compound [b] include a method of subjecting the metal-containing compound [b] to a hydrolysis-condensation reaction in a solvent containing water. In this case, another compound having a hydrolyzable group may be added, as necessary. The lower limit of the amount of water used in the hydrolysis-condensation reaction is preferably 0.2 times mol, more preferably 1 time mol, and still more preferably 3 times mol, in the number of moles, based on the hydrolyzable group of the metal-containing compound [b] and the like. The upper limit of the amount of water is preferably 20 times mol, more preferably 15 times mol, and still more preferably 10 times mol.

Examples of the method of performing the ligand substitution reaction using the metal-containing compound [b] include a method involving mixing the metal-containing compound [b] and the organic acid [a]. In this case, the metal-containing compound [b] and the organic acid [a] may be mixed in a solvent, or may be mixed without using a solvent. In the mixing, a base such as triethylamine may be added, as necessary. The addition amount of the base is, for example, 1 part by mass or more and 200 parts by mass or less based on 100 parts by mass of the total use amount of the metal-containing compound [b] and the organic acid [a].

The solvent to be used in the synthesis reaction of the compound [A](hereinafter also referred to as “solvent [d]”) is not particularly limited, and for example, the same solvents as those disclosed as examples of the solvent [C] described later can be used. Among them, alcohol-based solvents, ether-based solvents, ester-based solvents, and hydrocarbon-based solvents are preferable, alcohol-based solvents, ether-based solvents, and ester-based solvents are more preferable, monoalcohol-based solvents, polyhydric alcohol partial ether-based solvents, and polyhydric alcohol partial ether carboxylate-based solvents are still more preferable, and ethanol, n-propanol, isopropanol, 1-butanol, propylene glycol monoethyl ether, and propylene glycol monoethyl ether acetate are particularly preferable.

When the solvent [d] is used in the synthesis reaction of the compound [A], the solvent used may be removed after the reaction, but may be used as it is as the solvent [C] of the composition for forming a resist underlayer film without being removed after the reaction.

### [Compound [B]]

The compound [B] is a compound having an aromatic hydrocarbon ring structure (hereinafter also referred to as “aromatic hydrocarbon ring structure (I)”) and a partial structure represented by formula (1) (hereinafter also referred to as “partial structure (II)”) described later.

### [Aromatic Hydrocarbon Ring Structure (I)]

The aromatic hydrocarbon ring structure (I) is an aromatic hydrocarbon ring structure having 6 or more carbon atoms. In the present specification, the “number of carbon atoms of the aromatic hydrocarbon ring structure (I)” means the number of carbon atoms constituting the ring structure of the aromatic hydrocarbon ring structure (I). The “number of carbon atoms of the aromatic hydrocarbon ring structure (I)” does not include the number of carbon atoms constituting the partial structure (II).

The lower limit of the number of carbon atoms of the aromatic hydrocarbon ring structure (I) is 6, preferably 8, and more preferably 10. The upper limit of the number of carbon atoms is not particularly limited, and may be, for example, 100 or may be 80. When the number of carbon atoms of the aromatic hydrocarbon ring structure (I) is 6 or more, a film superior in etching resistance can be formed.

Examples of the aromatic hydrocarbon ring structure (I) include a monocyclic structure (that is, a benzene structure), a structure containing a fused polycyclic structure, a structure containing a ring assembly structure, and a structure obtained by combining these structures. In the present specification, the “fused polycyclic structure” means a ring structure in which a certain aromatic hydrocarbon ring and another aromatic hydrocarbon ring are bonded to each other by sharing two carbon atoms among polycyclic structures having two or more aromatic hydrocarbon rings. The “ring assembly structure” means a ring structure in which a certain aromatic hydrocarbon ring and another aromatic hydrocarbon ring are bonded to each other by a single bond without sharing any carbon atom among polycyclic structures having two or more aromatic hydrocarbon rings.

The fused polycyclic structure is not particularly limited as long as it has 6 or more carbon atoms, and examples thereof include a naphthalene structure, an anthracene structure, a phenalene structure, a phenanthrene structure, a pyrene structure, a fluorene structure, a perylene structure, a coronene structure, a trinaphthylene structure, a heptaphene structure, a heptacene structure, a pyranthrene structure, an ovalene structure, and a hexabenzocoronene structure.

The ring assembly structure is not particularly limited as long as it has 6 or more carbon atoms, and examples thereof include a biphenyl structure, a terphenyl structure, a tetraphenylbenzene structure, a pentaphenylbenzene structure, and a hexaphenylbenzene structure.

The aromatic hydrocarbon ring structure (I) is preferably a structure containing a fused polycyclic structure. When the aromatic hydrocarbon ring structure (I) is a structure containing a fused polycyclic structure, the etching resistance of a film formed by the composition can be further improved.

### [Partial Structure (II)]

The partial structure (II) is a partial structure represented by formula (1).

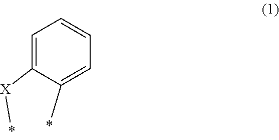

In the formula (1), X is a group represented by formula (i), (ii), (iii) or (iv) (hereinafter also referred to as “group (X)”) described later. * are bonding sites with two adjacent carbon atoms constituting the aromatic hydrocarbon ring structure described above (the aromatic hydrocarbon ring structure (I)).

In the compound [B], the partial structure (II) is bonded to the aromatic hydrocarbon ring structure (I). More specifically, the partial structure (II) is bonded to two adjacent carbon atoms constituting the aromatic hydrocarbon ring structure (I).

The lower limit of the number of the partial structure(s) (II) in the compound [B] is 1, and preferably 2. The upper limit of the number of the partial structures (II) is not particularly limited, and is preferably 10, and more preferably 6. When the compound [B] has two or more partial structures (II), the X's in the formula (1) are the same or different from each other.

### (Group (X))

The group (X) is a group represented by formula (i), (ii), (iii) or (iv) (hereinafter also referred to as “groups (X-i) to (X-iv)”).

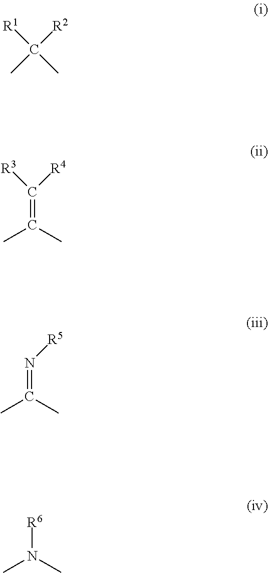

in the formula (i), R¹ is a hydrogen atom or a monovalent organic group having 1 to 20 carbon atoms. R² is a monovalent organic group having 1 to 20 carbon atoms.

In the formula (ii), R³ is a hydrogen atom or a monovalent organic group having 1 to 20 carbon atoms. R⁴ is a monovalent organic group having 1 to 20 carbon atoms.

In the formula (iii), R⁵ is a monovalent organic group having 1 to 20 carbon atoms.

In the formula (iv), R⁶ is a monovalent organic group having 1 to 20 carbon atoms.

In the present description, the “organic group” means a group containing at least one carbon atom.

Examples of the monovalent organic groups having 1 to 20 carbon atoms represented by R¹, R², R³, R⁴, R⁵, and R⁶ include a monovalent hydrocarbon group having 1 to 20 carbon atoms, a group having a divalent heteroatom-containing group between adjacent carbon atoms of the hydrocarbon group (hereinafter also referred to as “group (α)”), a group obtained by replacing some or all of hydrogen atoms of the hydrocarbon group with a monovalent heteroatom-containing group (hereinafter also referred to as “group (β)”), and a group obtained by replacing some or all of hydrogen atoms of the group (α) with a monovalent heteroatom-containing group (hereinafter also referred to as “group (γ)”).

In the present specification, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group containing no ring structure and composed only of a chain structure, and includes both a linear hydrocarbon group and a branched hydrocarbon group. The “alicyclic hydrocarbon group” means a hydrocarbon group containing only an alicyclic structure as a ring structure and containing no aromatic ring structure, and includes both a monocyclic alicyclic hydrocarbon group and a polycyclic alicyclic hydrocarbon group, provided that the alicyclic hydrocarbon group is not required to be composed only of an alicyclic structure, and may contain a chain structure as a part thereof. The “aromatic hydrocarbon group” means a hydrocarbon group containing an aromatic ring structure as a ring structure, provided that the aromatic hydrocarbon group is not required to be composed only of an aromatic ring structure, and may contain an alicyclic structure or a chain structure as a part thereof.

Examples of the monovalent hydrocarbon group having 1 to 20 carbon atoms include monovalent chain hydrocarbon groups having 1 to 20 carbon atoms, monovalent alicyclic hydrocarbon groups having 3 to 20 carbon atoms, monovalent aromatic hydrocarbon groups having 6 to 20 carbon atoms, and groups obtained by combining these groups.

Examples of the monovalent chain hydrocarbon group having 1 to 20 carbon atoms include alkyl groups such as a methyl group, an ethyl group, a n-propyl group, an i-propyl group, a n-butyl group, a sec-butyl group, and a tert-butyl group, alkenyl groups such as an ethenyl group, a propenyl group, and a butenyl group, and alkynyl groups such as an ethynyl group, a propynyl group, and a butynyl group.

Examples of the monovalent alicyclic hydrocarbon group having 3 to 20 carbon atoms include cycloalkyl groups such as a cyclopentyl group and a cyclohexyl group, cycloalkenyl groups such as a cyclopropenyl group, a cyclopentenyl group, and a cyclohexenyl group, bridged cyclic saturated hydrocarbon groups such as a norbornyl group, an adamantyl group, and a tricyclodecyl group, and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing group include —CO—, —CS—, —NH—, —O—, —S—, and groups obtained by combining them.

Examples of the monovalent heteroatom-containing group include a hydroxy group, a sulfanyl group, a cyano group, a nitro group, and halogen atoms.

The compound [B] preferably has at least one group selected from the group consisting of groups represented by formula (2-1) and groups represented by formula (2-2).

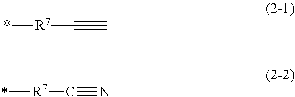

In the formulas (2-1) and (2-2), R⁷ each independently is a substituted or unsubstituted divalent hydrocarbon group having 1 to 20 carbon atoms or a single bond. * is a bond with a carbon atom in the compound [B].

In the formulas (2-1) and (2-2), as the divalent hydrocarbon group having 1 to 20 carbon atoms represented by R⁷, a group obtained by removing one hydrogen atom from the monovalent hydrocarbon group having 1 to 20 carbon atoms as R¹ or the like can be suitably employed. As the divalent hydrocarbon group having 1 to 20 carbon atoms represented by R⁷, a divalent chain hydrocarbon group having 1 to 10 carbon atoms is preferable, and a divalent chain saturated hydrocarbon group having 1 to 5 carbon atoms is more preferable, and a methanediyl group is still more preferable.

In addition to the aromatic hydrocarbon ring structure (I) and the partial structure (II), the compound [B] may contain an aromatic heterocyclic structure such as a furan structure, a pyrrole structure, a thiophene structure, a phosphole structure, a pyrazole structure, an oxazole structure, an isoxazole structure, a thiazole structure, an imidazole structure, a pyridine structure, a pyrazine structure, a pyrimidine structure, a pyridazine structure, a triazine structure, a quinoline structure, an isoquinoline structure, a quinoxaline structure, a quinazoline structure, a cinnoline structure, a benzofuran structure, an isobenzofuran structure, an indole structure, an isoindole structure, a benzothiophene structure, a benzimidazole structure, a benzoxazole structure, a benzisoxazole structure, a benzothiazole structure, or an acridine structure.

Examples of the compound [B] include compounds represented by formulas (1-1) to (1-20) (hereinafter also referred to as “compounds (1-1) to (1-20)”).

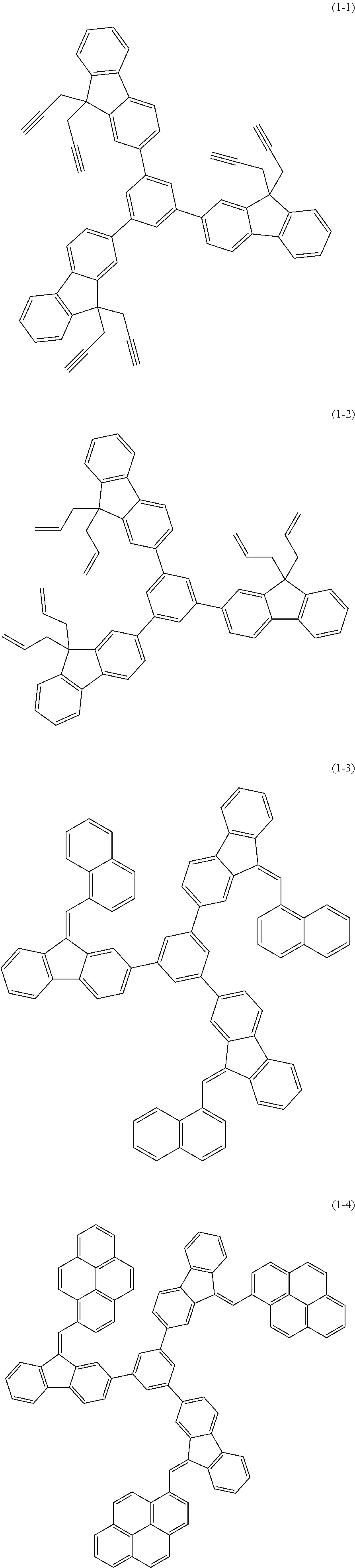

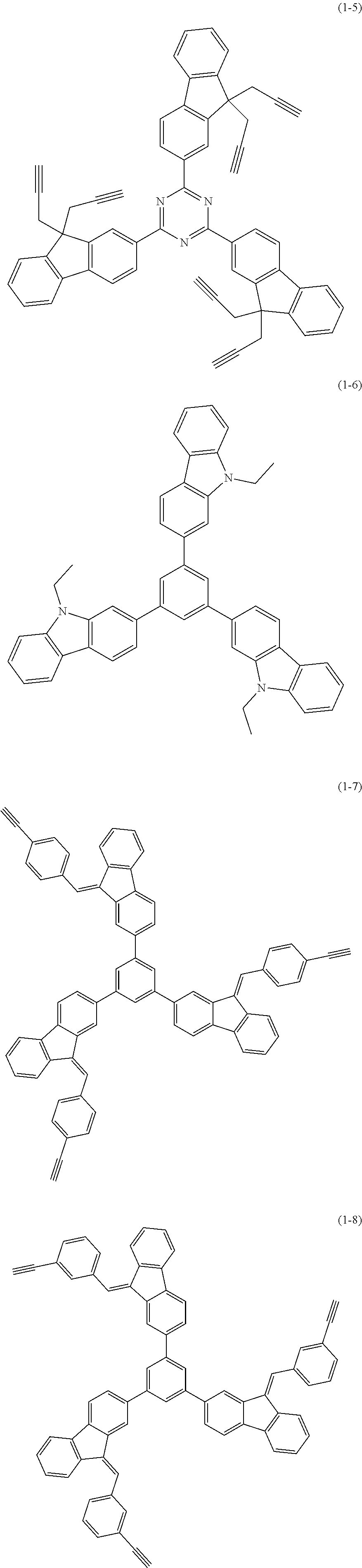

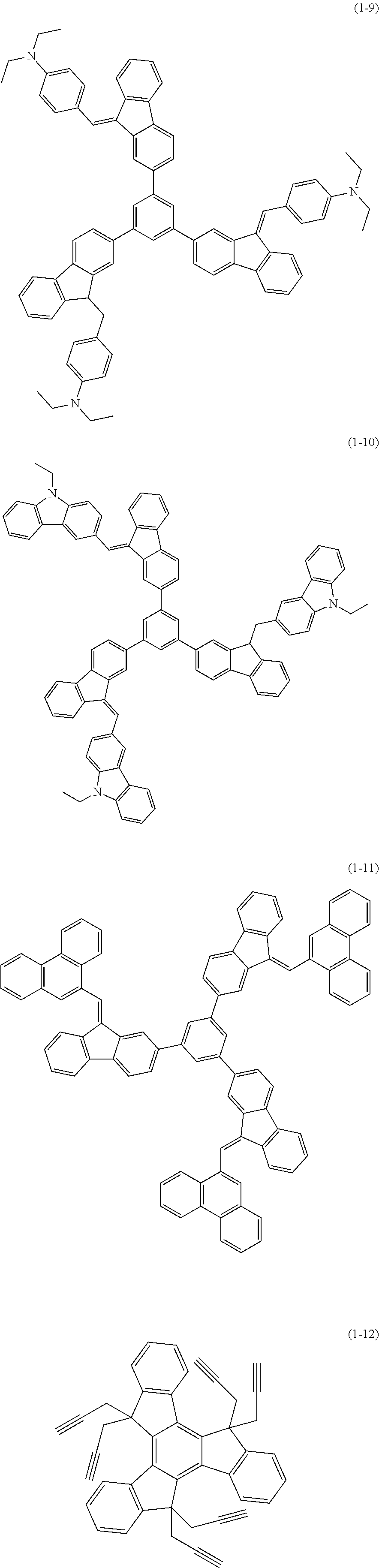

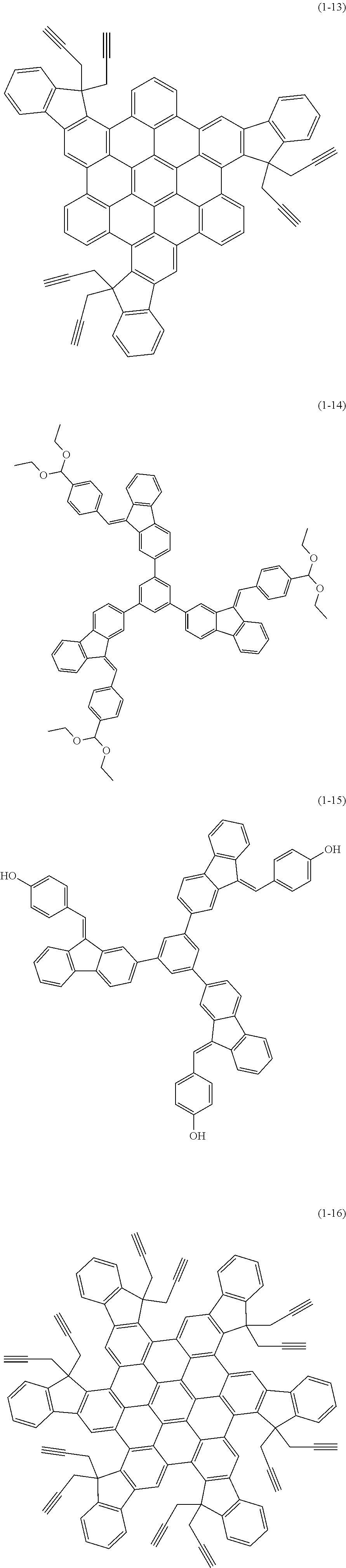

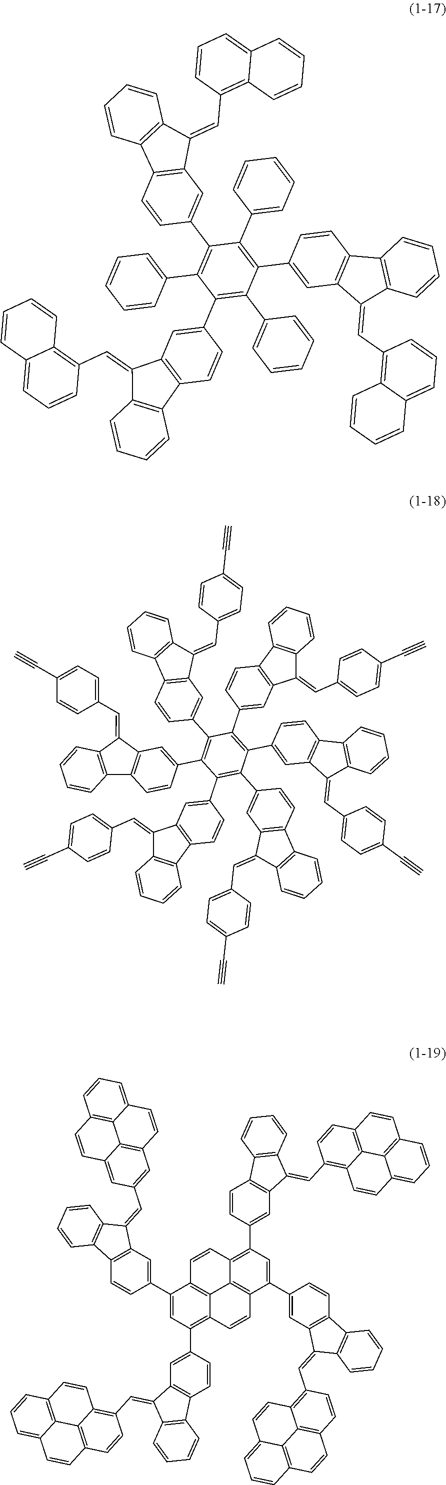

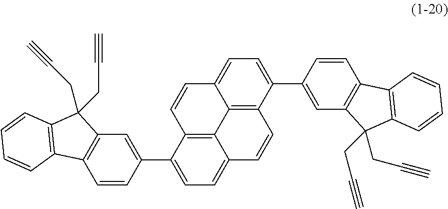 [SMILES: C#CCC1(CC#C)c2ccccc2-c2ccc(-c3ccc4ccc5c(-c6ccc7c(c6)C(CC#C)(CC#C)c6ccccc6-7)ccc6ccc3c4c65)cc21]

As the compound [B], compounds (1-1) to (1-13) are preferable.

The compound [B] may or may not have a substituent other than the aromatic hydrocarbon ring structure (I) and the partial structure (II) described above. As the compound [B], a compound having no other substituent is preferable. When the compound [B] does not have the other substituent, the content ratio of the carbon atom of the compound [B] is higher than when the compound [B] has the other substituent, so that the etching resistance of a film formed from the composition can be further improved.

Examples of the other substituent include a halogen atom, a hydroxy group, a nitro group, and a monovalent organic group having 1 to 20 carbon atoms. Examples of the monovalent organic group having 1 to 20 carbon atoms as the other substituent include groups the same as the groups enumerated as examples of the monovalent organic group having 1 to 20 carbon atoms represented by R¹ to R⁶ of the formulas (i) to (iv).

When the compound [B] has the other substituent, the site to which the other substituent is bonded is not particularly limited, and the other substituent may be bonded to either the aromatic hydrocarbon ring structure (I) or the partial structure (II).

The compound [B] preferably has no oxygen atom. Thereby, the storage stability of the composition can be improved.

The composition is suitable for pattern embedding of a substrate having a pattern.

The lower limit of the molecular weight of the compound [B] is preferably 300, more preferably 400, still more preferably 500, and particularly preferably 600. The upper limit of the molecular weight is preferably 5,000, more preferably 4,000, still more preferably 3,500, and particularly preferably 3,000.

The lower limit of the content of the aromatic compound is preferably 0.01 parts by mass, more preferably 0.05 parts by mass, still more preferably 0.1 parts by mass, and particularly preferably 0.2 parts by mass per 10 parts by mass of the metal compound. The upper limit of the content is preferably 50 parts by mass, more preferably 20 parts by mass, still more preferably 10 parts by mass, and particularly preferably 3 parts by mass.

### [Method for Synthesizing Compound [B]]

As a method for synthesizing the compound [B], the compound can be synthesized by a conventional method, for example, in accordance with the following synthesis scheme.

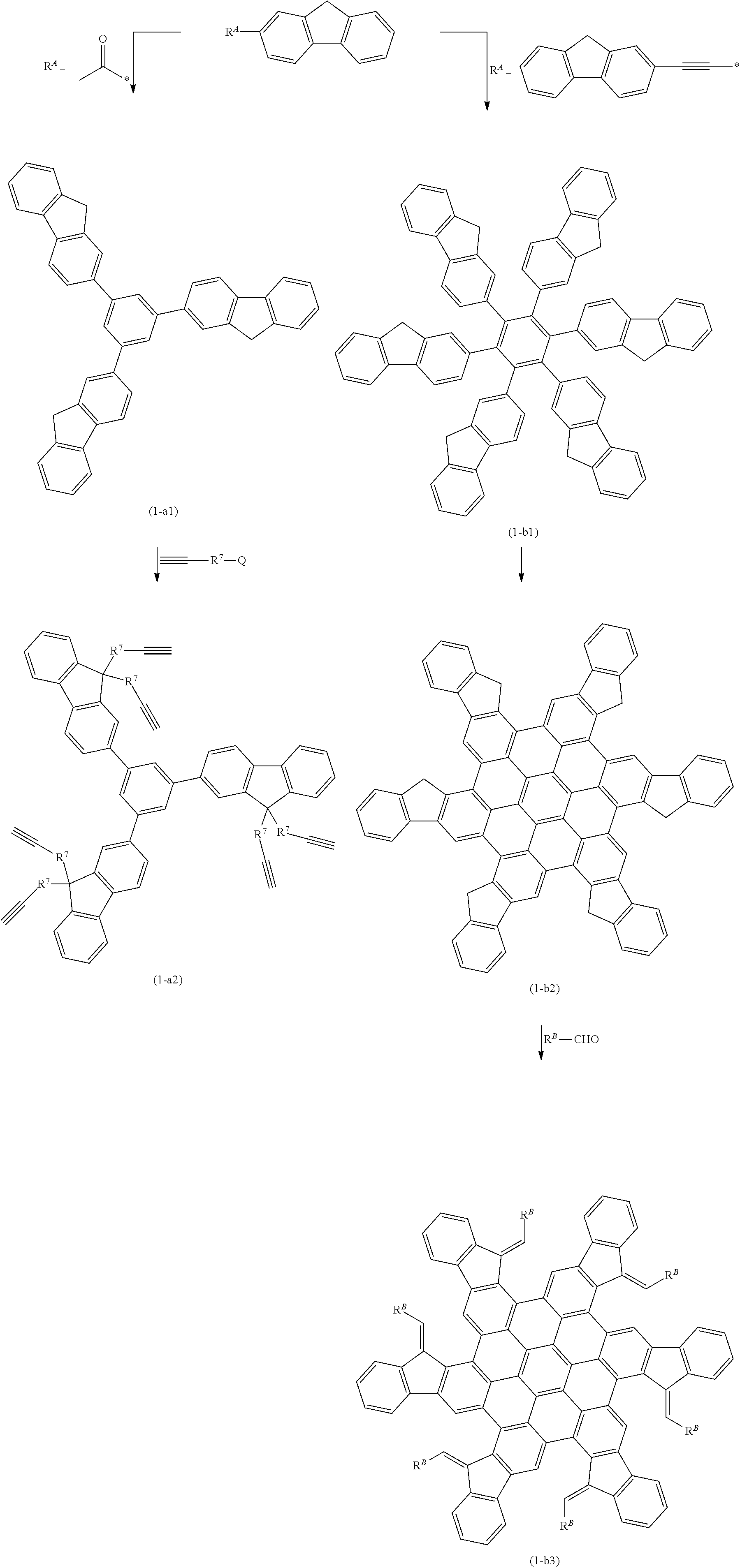

In the scheme, * is a bond with a fluorene ring. R⁷ has the same meaning as in the formulas (2-1) and (2-2). Q is a halogen atom. R^{B} has the same meaning as R⁴ in the formula (ii).

A substituted fluorene is prepared as a starting material, and cyclized in the presence of a catalyst or the like to afford an intermediate represented by the formula (1-a1) or (1-b1). For the intermediate represented by the formula (1-a1), a group represented by the formula (2-1) can be introduced by reacting the intermediate with a halogenated acetylene derivative that affords the partial structure (II). Thereby, the intended compound represented by the formula (1-a2) can be synthesized. The intermediate represented by the formula (1-b1) is made to undergo a cyclization reaction in the presence of a catalyst or the like, thereby affording an intermediate represented by the formula (1-b2). Subsequently, the intermediate represented by the formula (1-b2) is reacted with an aldehyde that affords the partial structure (II), whereby the intended compound represented by the formula (1-b3) can be synthesized. A compound having the partial structure (II) introduced therein may be synthesized without passing through the intermediate represented by the formula (1-b2) by directly reacting the intermediate represented by the formula (1-b1) with the aldehyde. Furthermore, the intermediate represented by the formula (1-a1) may be reacted with the aldehyde that affords the partial structure (II), or the intermediate represented by the formula (1-b1) or (1-b2) may be reacted with a halogenated acetylene derivative that affords the partial structure (II). Other structures can also be synthesized by appropriately selecting the structure or the like of a starting material, a halogenated acetylene derivative, an aldehyde.

### [Solvent [C]]

The solvent [C] is not particularly limited as long as it is a solvent capable of dissolving or dispersing at least the compound [A], the compound [B], other optional components, and the like. The composition may contain one or two or more of the solvent [C].

Examples of the solvent [C] include organic solvents. Examples of the organic solvent include alcohol-based solvents, ketone-based solvents, ether-based solvents, ester-based solvents, and nitrogen-containing solvents.

Examples of the alcohol-based solvents include monoalcohol-based solvents such as methanol, ethanol, n-propanol, isopropanol, and 1-butanol, and polyhydric alcohol-based solvents such as ethylene glycol, 1,2-propylene glycol, triethylene glycol, and tripropylene glycol.

Examples of the ketone-based solvents include chain ketone-based solvents such as methyl ethyl ketone, methyl isobutyl ketone, and 2-heptanone; and cyclic ketone-based solvents such as cyclohexanone.

Examples of the ether-based solvents include chain ether-based solvents such as n-butyl ether; polyhydric alcohol ether-based solvents such as cyclic ether-based solvents such as tetrahydrofuran and 1,4-dioxane; and polyhydric alcohol partial ether-based solvents such as propylene glycol monoethyl ether, tripropylene glycol monomethyl ether, and tetraethylene glycol monomethyl ether.

Examples of the ester-based solvents include carbonate-based solvents such as diethyl carbonate; acetic acid monoacetate ester-based solvents such as methyl acetate, ethyl acetate, and butyl acetate; lactone-based solvents such as γ-butyrolactone; polyhydric alcohol partial ether carboxylate-based solvents such as diethylene glycol monomethyl ether acetate and propylene glycol monomethyl ether acetate; and lactic acid ester-based solvents such as methyl lactate and ethyl lactate.

Examples of the nitrogen-containing solvents include chain nitrogen-containing solvents such as N,N-dimethylacetamide, and cyclic nitrogen-containing solvents such as N-methylpyrrolidone.

Additional examples include aromatic hydrocarbon-based solvents such as toluene, xylene, and mesitylene.

As the solvent [C], an ether-based solvent and/or an ester-based solvent is preferable, a polyhydric alcohol partial ether-based solvent and/or a polyhydric alcohol partial ether carboxylate-based solvent is more preferable, and propylene glycol monoethyl ether and/or propylene glycol monomethyl ether acetate is still more preferable.

The lower limit of the content of the solvent [C] accounting for in the total amount of the components contained in the composition is more preferably 50 mass %, preferably 60 mass %, and more preferably 70 mass %. The upper limit of the content is preferably 99% by mass, more preferably 95% by mass, and still more preferably 90% by mass. Owing to that the content of the solvent [C] is adjusted within the above range, the preparation of the composition can be facilitated, and the coatability can be improved.

### [Other Optional Components]

The composition may contain, for example, an acid generating agent, a macromolecular additive, a polymerization inhibitor, a surfactant, etc. as components other than those described above.

When the composition contains other optional components, the content of the other optional components in the composition can be appropriately determined according to the type, function, and so on of the other optional components to be used.

The acid generating agent is a compound that generates an acid by radiation irradiation and/or heating. The composition may contain one or two or more of the acid generating agent.

Examples of the acid generating agent include an onium salt compound and an N-sulfonyloxyimide compound.

When the composition contains a macromolecular additive, the composition can further enhance the coatability to a substrate and an organic underlayer film and the continuity of a film. The composition may contain one or two or more of the macromolecular additive.

Examples of the macromolecular additive include (poly)oxyalkylene-based macromolecular compounds, fluorine-containing macromolecular compounds, and non-fluorine-containing macromolecular compounds.

Examples of the (poly)oxyalkylene-based macromolecular compounds include: polyoxyalkylenes such as a (poly)oxyethylene-(poly)oxypropylene adduct; (poly)oxyalkyl ethers such as diethylene glycol heptyl ether, polyoxyethylene oleyl ether, polyoxypropylene butyl ether, polyoxyethylene polyoxypropylene-2-ethyl hexyl ether, and an adduct of oxyethylene-oxypropylene to a higher alcohol having 12 to 14 carbon atoms; (poly)oxyalkylene (alkyl) aryl ethers such as polyoxypropylene phenyl ether and polyoxyethylene nonyl phenyl ether; acetylene ethers obtained by addition polymerization of acetylene alcohol and an alkylene oxide, such as 2,4,7,9-tetramethyl-5-decyne-4,7-diol, 2,5-dimethyl-3-hexyne-2,5-diol, and 3-methyl-1-butyn-3-ol; (poly)oxyalkylene fatty acid esters such as diethylene glycol oleic acid ester, diethylene glycol lauric acid ester, and ethylene glycol distearic acid ester; (poly)oxyalkylene sorbitan fatty acid esters such as polyoxyethylene sorbitan monolauric acid ester and polyoxyethylene sorbitan trioleic acid ester; (poly)oxyalkylene alkyl (aryl) ether sulfuric acid ester salts such as polyoxypropylene methyl ether sodium sulfate and polyoxyethylene dodecyl phenol ether sodium sulfate; (poly)oxyalkylene alkyl phosphoric acid esters such as (poly)oxyethylene stearyl phosphoric acid ester; and (poly)oxyalkylene alkyl amines such as polyoxyethylene lauryl amine.

Examples of the fluorine-containing macromolecular compounds include compounds disclosed in JP-A-2011-89090. Examples of the fluorine-containing macromolecular compounds include compounds containing a repeating unit derived from a (meth)arylate compound having a fluorine atom and a repeating unit derived from a (meth)acrylate compound having two or more (preferably five or more) alkyleneoxy groups (preferably an ethyleneoxy group, a propyleneoxy group).

Examples of the non-fluorine-containing macromolecular compounds include compounds containing one kind or two or more kinds of repeating units derived from a (meth)acrylate monomer such as a linear or branched alkyl (meth)acrylate such as lauryl (meth)acrylate, 2-ethylhexyl (meth)acrylate, n-butyl (meth)acrylate, t-butyl (meth)acrylate, isooctyl (meth)acrylate, isostearyl (meth)acrylate, or isononyl (meth)acrylate, an alkoxyethyl (meth)acrylate such as methoxyethyl (meth)acrylate, an alkylene glycol di(meth)acrylate such as ethylene glycol di(meth)acrylate or 1,3-butylene glycol di(meth)acrylate, a hydroxyalkyl (meth)acrylate such as 2-hydroxyethyl (meth)acrylate, 2-hydroxypropyl (meth)acrylate, 2-hydroxybutyl (meth)acrylate, or 4-hydroxybutyl (meth)acrylate, dicyclopentenyloxyethyl (meth)acrylate, or nonylphenoxy polyethylene glycol (having a —(CH₂CH₂O)ₙ— structure, n=1 to 17) (meth)acrylate.

When the composition contains a polymerization inhibitor, the storage stability of the composition can be enhanced. The composition may contain one or two or more of the polymerization inhibitor.

Examples of the polymerization inhibitor include hydroquinone compounds such as 4-methoxyphenol and 2,5-di-tert-butylhydroquinone, and nitroso compounds such as N-nitrosophenylhydroxylamine and aluminum salts thereof.

When the composition contains a surfactant, the coatability to a substrate or an organic underlayer film and the continuity of a film can be further enhanced. The composition may contain one or two or more of the surfactant.

Examples of a commercially-available product of the surfactant include “Newcol 2320”, “Newcol 714-F”, “Newcol 723”, “Newcol 2307”, and “Newcol 2303” (which are all manufactured by NIPPON NYUKAZAI CO., LTD.), “Pionin D-1107-S”, “Pionin D-1007”, “Pionin D-1106-DIR”, “Newkalgen TG310”, “Pionin D-6105-W”, “Pionin D-6112”, and “Pionin D-6512” (which are all manufactured by TAKEMOTO OIL & FAT Co., Ltd.), “SURFYNOL 420” “SURFYNOL 440”, “SURFYNOL 465”, and “SURFYNOL 2502” (which are all manufactured by Air Products and Chemicals, Inc.), “MEGAFACE F171”, “MEGAFACE F172”, “MEGAFACE F173”, “MEGAFACE F176”, “MEGAFACE F177”, “MEGAFACE F141”, “MEGAFACE F142”, “MEGAFACE F143”, “MEGAFACE F144”, “MEGAFACE R30”, “MEGAFACE F437”, “MEGAFACE F475”, “MEGAFACE F479”, “MEGAFACE F482”, “MEGAFACE F562”, “MEGAFACE F563”, “MEGAFACE F780”, “MEGAFACE R-40”, “MEGAFACE DS-21”, “MEGAFACE RS-56”, “MEGAFACE RS-90”, and “MEGAFACE RS-72-K” (which are all manufactured by DIC Corporation), “Fluorad FC430” and “Fluorad FC431” (which are all manufactured by Sumitomo 3M Limited), “AsahiGuard AG710”, “Surflon S-382”, “Surflon SC-101”, “Surflon SC-102”, “Surflon SC-103”, “Surflon SC-104”, “Surflon SC-105”, and “Surflon SC-106 (which are all manufactured by AGC Inc.), and “FTX-218” and “NBX-15” (manufactured by NEOS Co., Ltd.).

### [Method for Preparing Composition for Film Formation]

The composition for film formation can be prepared by mixing the compound [A], the compound [B], the solvent [C] and, as necessary, an optional component in a prescribed ratio and preferably filtering the resulting mixture through a membrane filter having a pore size of 0.5 μm or less, or the like. In the composition, the compound [A] is preferably dissolved in the solvent [C].

### [Applying Step]

In the applying step, the composition for film formation is applied to a substrate. The method of the application of the composition for film formation is not particularly limited, and the application can be performed by an appropriate method such as spin coating, cast coating, or roll coating. As a result, a coating film is formed, and volatilization of the solvent [C] or the like occurs, so that a film (a metal hardmask) as a resist underlayer film is formed.

Examples of the substrate include metal or metalloid substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The substrate may have a pattern. Since the composition for film formation is superior in embeddability, even when the substrate has a pattern, a good film can be formed while the gap between patterns is filled. Examples of the shape of the pattern include a trench pattern, a line-and-space pattern, a hole pattern, and a pillar pattern. Examples of the trench pattern and the line-and-space pattern include a pattern including a recess having a width of 5 nm or more and 100 nm or less and a depth of 5 nm or more and 500 nm or less. Examples of the hole pattern include a pattern including holes having a diameter of 5 nm or more and 100 nm or less and a depth of 5 nm or more and 500 nm or less. Examples of the pillar pattern include a pattern including pillars each having a side of 5 nm or more and 100 nm or less and a height of 5 nm or more and 500 nm or less in the case of a quadrangular prism, and a pattern including pillars each having a diameter of 5 nm or more and 100 nm or less and a height of 5 nm or more and 500 nm or less in the case of a cylinder.

The lower limit of the average thickness of the resist underlayer film to be formed is preferably 3 nm, more preferably 5 nm, and still more preferably 10 nm. The upper limit of the average thickness is preferably 500 nm, more preferably 200 nm, and even more preferably 100 nm. The average thickness is measured as described in Examples.

The method for manufacturing a semiconductor substrate preferably further includes heating a coating film formed in the applying step (hereinafter also referred to as a “heating step”). The formation of the resist underlayer film is promoted by heating the coating film. More specifically, volatilization or the like of the solvent [C] is promoted by heating the coating film.

The heating of the coating film is usually performed in the atmosphere but may be performed in a nitrogen atmosphere. The lower limit of the temperature in heating is preferably 400° C., more preferably 420° C., and still more preferably 450° C. The upper limit of the temperature is preferably 600° C., more preferably 550° C., and still more preferably 500° C. The lower limit of a heating time is preferably 15 seconds, more preferably 30 seconds. The upper limit of the time is preferably 1,200 seconds, and more preferably 600 seconds.

### [Organic Underlayer Film Forming Step]

In this step, before the resist pattern forming step, an organic underlayer film is formed directly or indirectly on the substrate having the resist underlayer film formed through the applying step.

One example of a case where an organic underlayer film is indirectly formed on the substrate having the resist underlayer film is a case where the organic underlayer film is formed on a surface modification film formed on the resist underlayer film.

The organic underlayer film can be formed by applying a composition for forming an organic underlayer film. One example of a method for forming an organic underlayer film by coating with a composition for forming an organic underlayer film is a method in which the substrate having a resist underlayer film is directly or indirectly coated with a composition for forming an organic underlayer film, and a formed coating film is cured by heating or lithographic exposure. As the composition for forming an organic underlayer film, for example, “HM8006” manufactured by JSR Corporation can be used. Various conditions for heating or exposure can be appropriately determined according to the type of the composition for forming an organic underlayer film to be used.

### [Silicon-Containing Film Forming Step]

In this step, before the resist pattern forming step, a silicon-containing film is formed directly or indirectly on the substrate having the resist underlayer film formed through the applying step.

One example of a case where a silicon-containing film is indirectly formed on the substrate having a resist underlayer film is a case where a surface modification film for the resist underlayer film or the organic underlayer film is formed on the resist underlayer film.

The silicon-containing film can be formed by, for example, coating with a composition for forming a silicon-containing film, chemical vapor deposition (CVD), or atomic layer deposition (ALD). Examples of a method for forming a silicon-containing film by coating a composition for forming a silicon-containing film include a method including curing, by lithographic exposure and/or heating, a coating film formed by applying the composition for forming a silicon-containing film directly or indirectly to the resist underlayer film. As a commercially-available product of the composition for forming a silicon-containing film, for example, “NFC SOG01”, “NFC SOG04”, “NFC SOG080” (which are all manufactured by JSR Corporation), or the like can be used. By chemical vapor deposition (CVD) or atomic layer deposition (ALD), a silicon oxide film, a silicon nitride film, a silicon oxynitride film, or an amorphous silicon film can be formed.

### [Resist Pattern Forming Step]

In this step, a resist pattern is formed directly or indirectly on the resist underlayer film. Examples of a method for performing this step include a method using a resist composition, a method using nanoimprinting, and a method using a self-assembly composition. One example of a case where a resist pattern is indirectly formed on the resist underlayer film is a case where, when the method for manufacturing a semiconductor substrate includes the silicon-containing film forming step, a resist pattern is formed on the silicon-containing film.

Specifically, the method using a resist composition is performed by applying a resist composition in such a manner that a resist film to be formed has a predetermined thickness and then volatilizing a solvent in a coating film by pre-baking to form a resist film.

Examples of the resist composition include a positive or negative chemically amplified resist composition containing a radiation sensitive acid generating agent, a positive resist composition containing an alkali-soluble resin and a quinonediazide-based photosensitizer, a negative resist composition containing an alkali-soluble resin and a crosslinking agent, and a metal-containing resist composition containing metals such as tin, zirconium, and hafnium. It should be noted that in this step, a commercially-available resist composition may directly be used.

Then, the formed resist film is subjected to exposure to light by selective irradiation with radiation. Radiation used for lithographic exposure can appropriately be selected depending on the type of radiation sensitive acid generating agent used in the resist composition, and examples thereof include electromagnetic rays such as visible rays, ultraviolet rays, far-ultraviolet, X rays, and γ rays and corpuscular rays such as electron rays, molecular rays, and ion beams. Among them, far-ultraviolet is preferred, KrF excimer laser light (248 nm), ArF excimer laser light (193 nm), F₂ excimer laser light (wavelength: 157 nm), Kr₂ excimer laser light (wavelength: 147 nm), ArKr excimer laser light (wavelength: 134 nm), or extreme ultraviolet (wavelength: 13.5 nm, hereinafter also referred to as “EUV”) is more preferred, and KrF excimer laser light, ArF excimer laser light, or EUV is even more preferred.

After the exposure to light, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions of ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include various organic solvents mentioned above as examples of the solvent [C] contained in the composition.

After the development with a developer, a prescribed resist pattern is formed through washing and drying.

### [Etching Step]

In this step, a pattern is formed to the resist underlayer film by etching using the resist pattern as a mask. The number of times of etching may be once or twice or more, that is, etching may sequentially be performed using a pattern obtained by etching as a mask. However, from the viewpoint of obtaining a pattern having a further superior shape, etching is preferably performed twice or more. When performed a plurality of times, etching is performed to the silicon-containing film, the organic underlayer film, the resist underlayer film, and the substrate sequentially in order. Examples of an etching method include dry etching and wet etching. Among them, dry etching is preferred from the viewpoint of achieving a further superior pattern shape of the substrate. The dry etching uses, for example, gas plasma such as oxygen plasma. As a result of the etching, a semiconductor substrate having a prescribed pattern is obtained.

The dry etching can be performed using, for example, a known dry etching device. An etching gas used for the dry etching can appropriately be selected depending on, for example, a mask pattern or the elemental composition of a film to be etched, and examples thereof include a fluorine-based gas such as CHF₃, CF₄, C₂F₆, C₃F₈, or SF₆, a chlorine-based gas such as Cl₂ or BCl₃, an oxygen-based gas such as O₂, O₃, or H₂O, a reductive gas such as H₂, CO, CO₂, CH₄, C₂H₂, C₂H₄, C₂H₆, C₃H₄, C₃H₆, C₃He, HF, HI, HBr, HCl, NO, NH₃, or BCl₃, and an inert gas such as He, N₂, or Ar. These gases can also be used in admixture. When the substrate is etched using the pattern of the resist underlayer film as a mask, a fluorine-based gas is usually used.

### <<Composition for Film Formation>>

The composition for film formation contains a compound [A], a compound [B], and a solvent [C]. As such a composition for film formation, a composition for film formation to be used in the above-described method for manufacturing a semiconductor substrate can be suitably employed.

### EXAMPLES

Hereinafter, Examples are described. The following Examples merely illustrate typical Examples of the present disclosure, and the Examples should not be construed to narrow the scope of the present disclosure.

The concentration of components other than the solvent in the mixture containing the compound [A] in this Example, the average thickness and the weight average molecular weight (Mw) of the film were measured by the methods described below.

[Concentration of Components Other than Solvent in Mixture Containing Compound [A]]

By firing 0.5 g of a mixture containing the compound [A] at 250° C. for 30 minutes, measuring a mass of the residue thus obtained, and dividing the mass of the residue by the mass of the solution containing the compound [A], the concentration (% by mass) of the components other than the solvent in the mixture containing the compound [A] was calculated.

### [Average Thickness of Resist Underlayer Film]

The average thickness of a resist underlayer film was determined by measuring film thicknesses at arbitrary nine points at intervals of 5 cm including the center of the resist underlayer film formed on a 12-inch silicon wafer (substrate), using a spectroscopic ellipsometer (“M2000D” available from J. A. WOOLLAM Co.) and calculating the average value of the film thicknesses.

### [Weight-Average Molecular Weight (Mw))]

Unless otherwise stated, the Mw of a polymer was measured by gel permeation chromatography (detector: differential refractometer) with monodisperse polystyrene standards using GPC columns (“G2000HXL”×2, “G3000HXL”×1, and “G4000HXL”×1) manufactured by Tosoh Corporation under the analysis conditions specified by flow rate: 1.0 mL/min; elution solvent: tetrahydrofuran; and column temperature: 40° C.

### <Synthesis of Compound [A]>

The compound [m], the compound [x], the solvent [d], and the solvent [C] used for the synthesis of the compound [A] are listed below. In the following synthesis examples, unless otherwise specified, “parts by mass” means a value taken when the mass of the compound [m] used is 100 parts by mass. In addition, the “molar ratio” means a value taken when the amount of the compound [m] used is 1. The concentrations (% by mass) of components other than the solvent in the mixture containing the compound [A] are also shown in Table 1.

The following compounds were used as the compound [m].
m-1: Tetra-n-propoxyzirconium(IV)
m-2: Tetra-n-butoxyzirconium(IV)
m-3: Tetra-n-propoxyhafnium(IV)
m-4: Tetraisopropoxytitanium(IV)
m-5: Pentaethoxytantalum(V)

The following compounds were used as the compound [x].
x-1: Propionic acid
x-2: Butyric acid
x-3: Isobutyric acid
x-4: Methacrylic acid
x-5: 2-Ethylhexanoic acid
x-6: Acetylacetone
x-7: Diethanolamine

The following compounds were used as the solvent [d].
d-1: n-Propyl alcohol
d-2: Ethanol
d-3: 1-Butanol
d-4: Isopropanol

As the solvent [C], the following compounds were used.
C-1: Propylene glycol monomethyl ether acetate
C-2: Propylene glycol monoethyl ether

### [Synthesis Example 1-1] (Synthesis of Compound [A](A-1))

The compound (m-1) (molar ratio of 1) and the solvent (d-1) (40 parts by mass) were charged into a reaction vessel under a nitrogen atmosphere. In the reaction vessel, the compound (x-1) (molar ratio: 5) was added dropwise over 20 minutes with stirring at 50° C. The reaction was then carried out at 80° C. for 3 hours. After the completion of the reaction, the inside of the reaction vessel was cooled to 30° C. or lower. The precipitate obtained via the cooling was collected by filtration, washed with n-hexane (100 parts by mass), and then vacuum-dried, affording compound (A-1).

### [Synthesis Example 1-2] (Synthesis of Compound [A](A-2))

The compound (m-1) (molar ratio of 1) and the solvent (d-1) (200 parts by mass) were charged into a reaction vessel under a nitrogen atmosphere. In the reaction vessel, the compound (x-2) (molar ratio: 5) was added dropwise over 20 minutes with stirring at 50° C. The reaction was then carried out at 80° C. for 3 hours. After the completion of the reaction, the inside of the reaction vessel was cooled to 30° C. or lower. After 900 parts by mass of the solvent (C-1) was added to the cooled reaction solution, the solvent (d-1), the alcohol generated via the reaction, and the excess solvent (C-1) were removed using an evaporator, affording a mixture containing compound (A-2). The concentration of the components other than the solvent in the mixture containing the compound [A](A-2) was 14% by mass.

### [Synthesis Examples 1-10 and 1-14] (Synthesis of Compounds [A] (A-10) and (A-14))

Compounds [A](A-10) and (A-14) were obtained in the same manner as in Synthesis Example 1-1 except that the compound [m], the compound [x] and the solvent [d] of the type and use amount given in the following Table 1 were used.

### [Synthesis Examples 1-3 to 1-9 and 1-11 to 1-13] (Synthesis of Compounds [A](A-3) to (A-9) and (A-11) to (A-13))

Mixtures containing compounds [A](A-3) to (A-9) and (A-11) to (A-13) were obtained in the same manner as in Synthesis Example 1-2 except that the compound [m], the compound [x], the solvent [d], and the solvent [C] of the type and use amount given in the following Table 1 were used.

### [Synthesis Example 1-15] (Synthesis of Compound [A](A-15))

The compound (m-4) (molar ratio of 1) was charged into a reaction vessel under a nitrogen atmosphere. In the reaction vessel, the compound (x-6) (molar ratio: 2) was added dropwise over 30 minutes with stirring at room temperature (25° C. to 30° C.). The reaction was then carried out at 60° C. for 2 hours. After the completion of the reaction, the inside of the reaction vessel was cooled to 30° C. or lower. The cooled reaction solution was diluted with the solvent (d-4) (900 parts by mass). In the reaction vessel, water (molar ratio: 2) was added dropwise over 10 minutes with stirring at room temperature (25° C. to 30° C.). A hydrolysis-condensation reaction was then carried out at 60° C. for 2 hours. After the completion of the hydrolysis-condensation reaction, the inside of the reaction vessel was cooled to 30° C. or lower. After 1,000 parts by mass of the solvent (C-2) was added to the cooled reaction solution, water, isopropanol, the alcohol generated via the reaction, and the excess solvent (C-2) were removed using an evaporator, affording a mixture containing compound (A-15). The concentration of the components other than the solvent in the mixture containing the compound [A](A-15) was 13% by mass.

### [Synthesis Example 1-16] (Synthesis of Compound [A](A-16))

A mixture containing compound [A](A-16) was obtained in the same manner as in Synthesis Example 1-15 except that the compound [m], the compound [x], the solvent [d], and the solvent [C] of the type and use amount given in the following Table 1 were used.

TABLE 1

| | | | | | | | | Concentration of |
|---|---|---|---|---|---|---|---|---|
| | | | | | | | | components other |
| | | | | | | | | than solvent in |
| | | | | | | | | mixture containing |
| | Compound | Compound [m] | | Compound [x] | | Solvent [d] | Solvent [C] | compound [A] |
| | [A] | Type | mol % | Type | mol % | Type | Type | (% by mass) |
| Synthesis | A-1 | m-1 | 1 | x-1 | 5 | d-1 | — | 100 |
| Example 1-1 | | | | | | | | |
| Synthesis | A-2 | m-1 | 1 | x-2 | 5 | d-1 | C-1 | 14 |
| Example 1-2 | | | | | | | | |
| Synthesis | A-3 | m-1 | 1 | x-3 | 5 | d-1 | C-1 | 14 |
| Example 1-3 | | | | | | | | |
| Synthesis | A-4 | m-1 | 1 | x-4 | 1 | d-1 | C-1 | 13 |
| Example 1-4 | | | | | | | | |
| Synthesis | A-5 | m-1 | 1 | x-4 | 2 | d-1 | C-1 | 13 |
| Example 1-5 | | | | | | | | |
| Synthesis | A-6 | m-1 | 1 | x-4 | 3 | d-1 | C-1 | 13 |
| Example 1-6 | | | | | | | | |
| Synthesis | A-7 | m-1 | 1 | x-4 | 5 | d-1 | C-1 | 13 |
| Example 1-7 | | | | | | | | |
| Synthesis | A-8 | m-1 | 1 | x-5 | 5 | d-1 | C-1 | 14 |
| Example 1-8 | | | | | | | | |
| Synthesis | A-9 | m-2 | 1 | x-4 | 5 | d-3 | C-1 | 13 |
| Example 1-9 | | | | | | | | |
| Synthesis | A-10 | m-3 | 1 | x-4 | 5 | d-1 | — | 100 |
| Example 1-10 | | | | | | | | |
| Synthesis | A-11 | m-4 | 1 | x-4 | 5 | d-4 | C-1 | 13 |
| Example 1-11 | | | | | | | | |
| Synthesis | A-12 | m-5 | 1 | x-3 | 6 | d-2 | C-1 | 13 |
| Example 1-12 | | | | | | | | |
| Synthesis | A-13 | m-2 | 1 | x-6 | 1 | d-3 | C-2 | 14 |
| Example 1-13 | | | | | | | | |
| Synthesis | A-14 | m-2 | 1 | x-6 | 4 | d-3 | — | 100 |
| Example 1-14 | | | | | | | | |
| Synthesis | A-15 | m-4 | 1 | x-6 | 2 | d-4 | C-2 | 13 |
| Example 1-15 | | | | | | | | |
| Synthesis | A-16 | m-4 | 1 | x-7 | 2 | d-4 | C-1 | 20 |
| Example 1-16 | | | | | | | | |

### <Synthesis of Compound [B]>

As the compound [B], compounds represented by formulas (B-1) to (B-13) (hereinafter also referred to as “compounds (B-1) to (B-13)”) were synthesized by the following procedures.

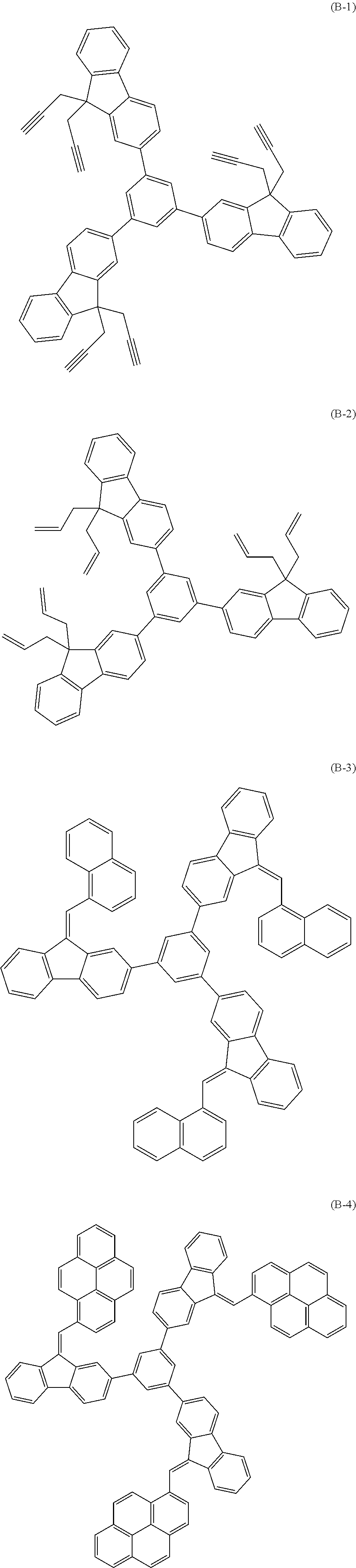

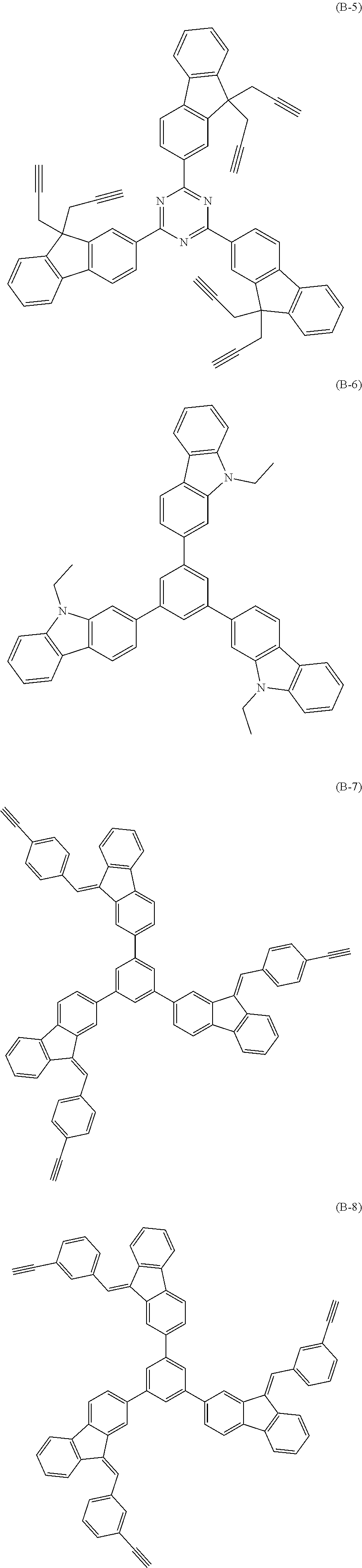

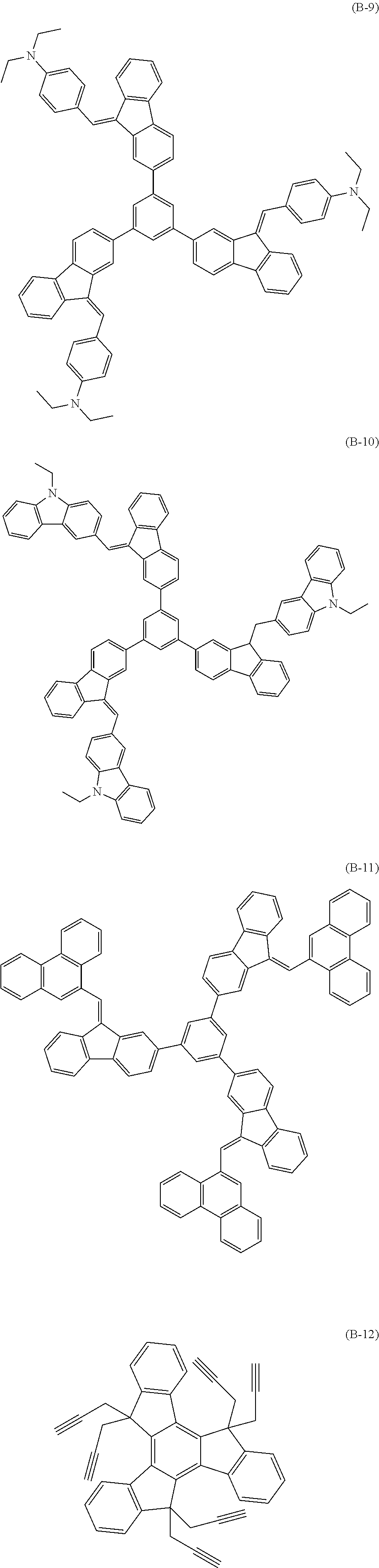

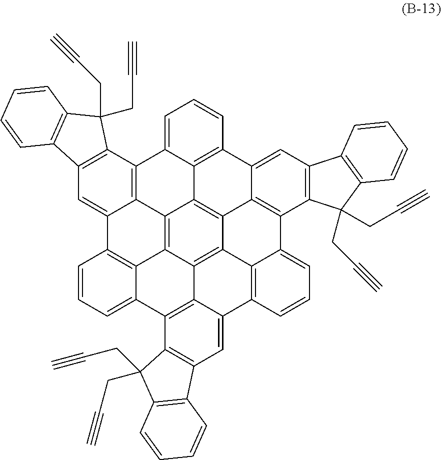 [SMILES: C#CCC1(CC#C)c2ccccc2-c2cc3c4cccc5c6c7c(cc8c9cccc%10c%11c%12c(cc%13c%14cccc%15c(c21)c3c1c(c45)c(c86)c(c9%10)c(c%13%11)c1c%14%15)-c1ccccc1C%12(CC#C)CC#C)-c1ccccc1C7(CC#C)CC#C]

### [Synthesis Example 1] (Synthesis of Compound (B-1))

Under a nitrogen atmosphere, 20.0 g of 2-acetylfluorene and 20.0 g of m-xylene were charged into a reaction vessel, and dissolved at 110° C. Then, 3.14 g of dodecylbenzenesulfonic acid was added, and the mixture was heated to 140° C. and reacted for 16 hours. After completion of the reaction, 80 g of xylene was added to the reaction solution to dilute the solution, and then the solution was cooled to 50° C. and charged into 500 g of methanol and reprecipitated. The resulting precipitate was washed with toluene, then the solid was collected on a filter paper and dried, affording a compound (a-1) represented by formula (α-1).

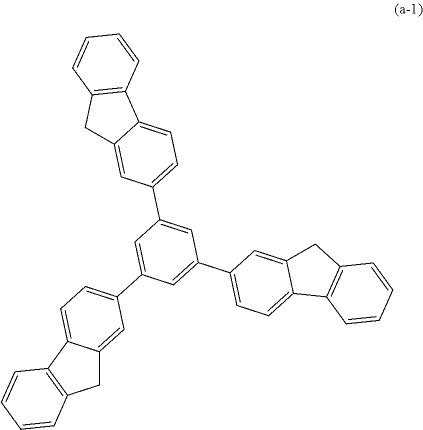 [SMILES: c1ccc2c(c1)Cc1cc(-c3cc(-c4ccc5c(c4)Cc4ccccc4-5)cc(-c4ccc5c(c4)Cc4ccccc4-5)c3)ccc1-2]

Under a nitrogen atmosphere, 10.0 g of the compound (a-1), 18.8 g of propargyl bromide, and 50 g of toluene were added to a reaction vessel, and stirred. Then, 25.2 g of a 50% by mass aqueous sodium hydroxide solution and 1.7 g of tetrabutylammonium bromide were added thereto, and the mixture was reacted at 92° C. for 12 hours. The reaction solution was cooled to 50° C., and then 25 g of tetrahydrofuran was added thereto. After the aqueous phase was removed, 50 g of a 1% by mass aqueous oxalic acid solution was added, and the mixture was subjected to liquid-liquid separation-extraction. Then, the mixture was charged into hexane and reprecipitated. The precipitate was collected on a filter paper and dried, affording a compound (B-1).

### [Synthesis Example 2] (Synthesis of Compound (B-2))

The compound (B-2) was obtained in the same manner as in Synthesis Example 1 except that 18.8 g of propargyl bromide was changed to 19.1 g of allyl bromide.

### [Synthesis Example 3] (Synthesis of Compound (B-3))

The compound (B-3) was obtained in the same manner as in Synthesis Example 1 except that 18.8 g of propargyl bromide was changed to 9.9 g of 1-naphthaldehyde.

### [Synthesis Example 4] (Synthesis of Compound (B-4))

The compound (B-4) was obtained in the same manner as in Synthesis Example 1 except that 18.8 g of propargyl bromide was changed to 14.6 g of 1-formylpyrene.

### [Synthesis Example 5] (Synthesis of Compound (B-5))

Under a nitrogen atmosphere, 10.0 g of 2-cyanofluorene and 88.8 g of dichloromethane were added to a reaction vessel, and the mixture was cooled to 5° C. Then, 7.9 g of trifluoromethanesulfonic acid was added dropwise, and the mixture was reacted at 20° C. to 25° C. for 24 hours. The reaction solution was neutralized by adding a large amount of an aqueous sodium bicarbonate solution, and then the precipitated solid was collected on a filter paper, washed with dichloromethane, and dried, affording a compound represented by formula (a-2).

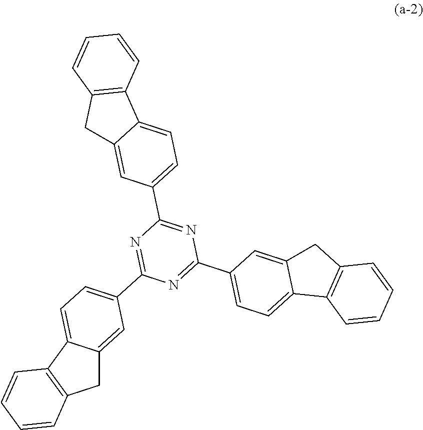 [SMILES: c1ccc2c(c1)Cc1cc(-c3nc(-c4ccc5c(c4)Cc4ccccc4-5)nc(-c4ccc5c(c4)Cc4ccccc4-5)n3)ccc1-2]

Under a nitrogen atmosphere, 5.0 g of the compound (a-2), 7.5 g of propargyl bromide, 12.6 g of a 50% by mass aqueous sodium hydroxide solution, 0.8 g of tetrabutylammonium bromide, and 25.7 g of toluene were added to a reaction vessel, and the mixture was reacted at 92° C. for 12 hours. The reaction solution was cooled to 50° C., and then 25 g of tetrahydrofuran was added to dilute the solution. After the aqueous phase was removed, 50 g of a 1% by mass aqueous oxalic acid solution was added, and the mixture was subjected to liquid-liquid separation-extraction. Then, the mixture was charged into hexane and reprecipitated. The precipitate was collected on a filter paper and dried, affording the compound (B-5).

### Synthesis Example 6

Under a nitrogen atmosphere, 15.0 g of 2-acetyl-9-ethylcarbazole, 14.9 g of thionyl chloride, and 2.8 g of ethanol were added to a reaction vessel, and the mixture was reacted at 80° C. for 8 hours. To the resulting reaction solution were added 50 g of water and 50 g of dichloromethane, and the mixture was subjected to liquid-liquid separation-extraction. Then, the resulting organic layer was concentrated using an evaporator, and dried, affording the compound (B-6).

### [Synthesis Example 7] (Synthesis of Compound (B-7))

Under a nitrogen atmosphere, 10.0 g of the compound (a-1), 12.76 g of 4-(trimethylsilylethynyl)benzaldehyde, and 50 g of tetrahydrofuran were added to a reaction vessel, and the mixture was stirred. Then, 37.9 g of a 20% by mass aqueous sodium hydroxide solution and 1.7 g of tetrabutylammonium bromide were added thereto, and the mixture was reacted at 35° C. for 3 hours. The reaction solution was cooled to room temperature, and then, 15 g of methyl isobutyl ketone was added. After the aqueous phase was removed, liquid-liquid separation-extraction with 50 g of a 1% by mass aqueous oxalic acid solution was repeated three times, and the mixture was charged into hexane and reprecipitated. The precipitate was collected on a filter paper and dried, affording the compound (B-7).

### [Synthesis Example 8] (Synthesis of Compound (B-8))

The compound (B-8) was obtained in the same manner as in Synthesis Example 7 except that 4-(trimethylsilylethynyl)benzaldehyde was changed to 3-(trimethylsilylethynyl)benzaldehyde.

### [Synthesis Example 9] (Synthesis of Compound (B-9))

The compound (B-9) was obtained in the same manner as in Synthesis Example 1 except that 18.8 g of propargyl bromide was changed to 6.5 g of 4-diethylaminobenzaldehyde.

### [Synthesis Example 10] (Synthesis of Compound (B-10))

The compound (B-10) was obtained in the same manner as in Synthesis Example 1 except that 18.8 g of propargyl bromide was changed to 12.3 g of N-ethylcarbazole-3-carboxyaldehyde.

### [Synthesis Example 11] (Synthesis of Compound (B-11))

The compound (B-11) was obtained in the same manner as in Synthesis Example 1 except that 18.8 g of propargyl bromide was changed to 11.4 g of 9-phenanthrenecarbaldehyde.

### [Synthesis Example 12] (Synthesis of Compound (B-12))

Under a nitrogen atmosphere, 10.0 g of truxene, 31.3 g of propargyl bromide, and 50 g of toluene were added to a reaction vessel, and stirred. Then, 42.0 g of a 50% by mass aqueous sodium hydroxide solution and 2.8 g of tetrabutylammonium bromide were added thereto, and the mixture was reacted at 92° C. for 12 hours. The reaction solution was cooled to 50° C., then the aqueous phase was removed, and 50 g of a 1% by mass aqueous oxalic acid solution was added, followed by liquid-liquid separation-extraction. Then, the resulting mixture was charged into a methanol/water (70/30 (mass ratio)) mixed solvent, and reprecipitated. The precipitate was collected on a filter paper and dried, affording the compound (B-12).

### [Synthesis Example 13] (Synthesis of Compound (B-13))

Under a nitrogen atmosphere, 20.0 g of 2-phenylethynylfluorene and 200 g of 1,4-dioxane were charged into a reaction vessel, and dissolved at 50° C. Then, 1.28 g of dicobalt octacarbonyl was added, and the mixture was heated to 110° C. and reacted for 12 hours. After completion of the reaction, the reaction solution was cooled to room temperature, and 600 g of methanol and 60.0 g of water were added, affording a precipitate. The resulting precipitate was collected on a filter paper, washed with a large amount of methanol, and dried, affording a compound (a-3) represented by formula (α-3).

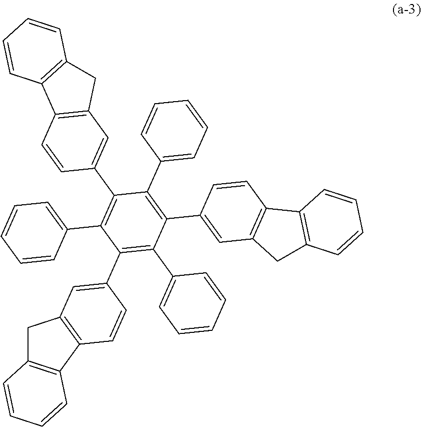 [SMILES: c1ccc(-c2c(-c3ccc4c(c3)Cc3ccccc3-4)c(-c3ccccc3)c(-c3ccc4c(c3)Cc3ccccc3-4)c(-c3ccccc3)c2-c2ccc3c(c2)Cc2ccccc2-3)cc1]

Under a nitrogen atmosphere, 15.0 g of the compound (a-3) and 760 g of dichloromethane were charged into a reaction vessel, dissolved at room temperature, and then the solution was cooled to 0° C. Then, a solution prepared by dissolving 60.9 g of anhydrous iron(III) chloride in 380 g of nitromethane was added dropwise. The mixture was reacted at 0° C. for 2 hours, then heated to 20° C., and further reacted for 2 hours. After completion of the reaction, 1,140 g of methanol was added, affording a precipitate. The resulting precipitate was collected on a filter paper, washed with a large amount of methanol and tetrahydrofuran (hereinafter also referred to “THF”), and dried, affording a compound (a-4) represented by formula (α-4).

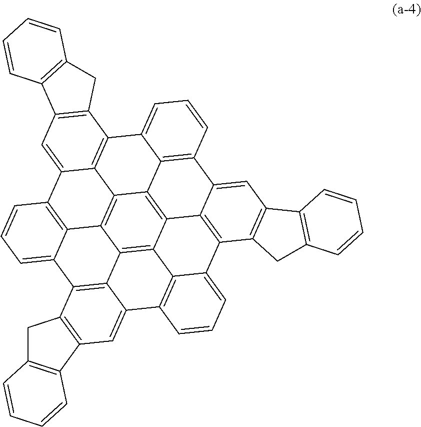 [SMILES: c1ccc2c(c1)Cc1c-2cc2c3cccc4c5c6c(cc7c8cccc9c%10c%11c(cc%12c%13cccc%14c1c2c1c(c34)c(c75)c(c89)c(c%12%10)c1c%13%14)-c1ccccc1C%11)-c1ccccc1C6]

Under a nitrogen atmosphere, 14.0 g of the compound (a-4), 200 g of THF, and 19.0 g of potassium t-butoxide were added to a reaction vessel, and stirred at 60° C. for 30 minutes. Then, the mixture was cooled to −40° C., 20.1 g of propargyl bromide was added dropwise, and the resulting mixture was reacted at 0° C. for 2 hours. After completion of the reaction, 500 g of a 5% by mass aqueous oxalic acid solution and 100 g of methyl isobutyl ketone were added. After the aqueous phase was removed, liquid-liquid separation-extraction with water was performed, and the organic layer was charged into hexane and reprecipitated. The precipitate was collected on a filter paper and dried, affording compound (B-13).

### <Preparation of Composition>

The compounds [A], the compounds [B], the solvents [C], and other optional components [F] are described below.

The compounds (A-1) to (A-16) synthesized above were used as the compound [A].

The compounds (B-1) to (B-13) were used as the compounds [B].

In addition to (C-1) and (C-2) used for the synthesis of the compound [A], the following compounds were used as the solvent [C].
C-3: Cyclohexanone
C-4: 2-Heptanone
C-5: Mesitylene
C-6: Butyl acetate

The following compounds were used as other optional component [F].
F-1: 4-Methoxyphenol
F-2: Surfactant (“NBX-15” manufactured by NEOS Co., Ltd.)
F-3: Surfactant (“F₅₆₃” manufactured by DIC Corporation)
F-4: Polymer (F-4) represented by formula (The number attached to each repeating unit denotes the content ratio (mol %) of the repeating unit, and the same applies hereinafter.)

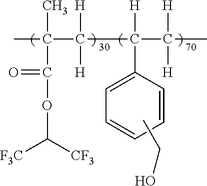

F-5: Polymer (F-5) represented by formula

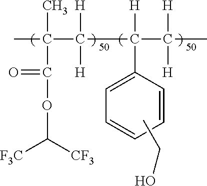

F-6: Polymer (F-6) represented by formula

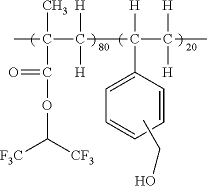

### (Synthesis of Polymer (F-4))

1,1,1,3,3,3-Hexafluoroisopropyl methacrylate (43.0 g) and vinylbenzyl alcohol (57.0 g) were dissolved in 130 g of methyl isobutyl ketone, and 19.6 g of dimethyl 2,2′-azobis(2-methylpropionate) was added to prepare a monomer solution. In a nitrogen atmosphere, 70 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether acetate, and methyl isobutyl ketone was removed by concentration under reduced pressure, affording a propylene glycol monomethyl ether acetate solution of polymer (F-4). The Mw of the polymer (F-4) was 4,200.

### (Synthesis of Polymers (F-5) to (F-6))

Propylene glycol monomethyl ether acetate solutions of the polymers (F-5) to (F-6) were obtained in the same manner as in the synthesis of the polymer (F-4) except that monomers capable of affording the structural units shown in the above formulas in the respective content ratios (mol %) were used. The Mw of the polymer (F-5) was 4,000, and the Mw of the polymer (F-6) was 4,300.

### [Example 1-1] Preparation of Composition (J-1)

As shown in the following Table 2, 0.03 parts by mass of the compound [B](B-1) and 90 parts by mass of (C-3) as the solvent [C] were mixed per 10 parts by mass of the compound [A](A-1). The resulting solution was filtered through a polytetrafluoroethylene (PTFE) filter having a pore size of 0.2 μm to prepare composition (J-1). “-” for compound [B] and other optional components [F] in Table 2 indicates that the compound [B] and the other optional components [F] were not used. The same applies hereinafter.

### [Example 1-2] Preparation of Composition (J-2)

As shown in the following Table 2, a mixture containing the compound [A](A-2) and (C-1) as the solvent [C] were mixed such that the amount of the compound [B](B-1) was 0.03 parts by mass and the amount of the solvent [C](including the solvent [C] contained in the mixture containing the compound [A]) was 90 parts by mass per 10 parts by mass of the components other than the solvent in the compound [A](A-2). The resulting solution was filtered through a polytetrafluoroethylene (PTFE) filter having a pore size of 0.2 μm to prepare composition (J-2).

### [Examples 1-3 to 1-47] Preparation of Compositions (J-3) to (J-47)

Compositions (J-3) to (J-47) were prepared in the same manner as in Example 1-1 or Example 1-2 except that the type and content of each component were set as shown in the following Table 2.

### [Comparative Examples 1-1] Preparation of Compositions (j-1)

Composition (j-1) was prepared in the same manner as in Example 1-2 except that the type and content of each component were set as shown in the following Table 2.

TABLE 2

| | | Compound [A] or | | | | | | | |
|---|---|---|---|---|---|---|---|---|---|
| | | components other than | | | | | | | |
| | | solvent in mixture | | | | | | | |
| | | containing compound | | | | | | Other optional | |
| | | [A] | | Compound [B] | | Solvent [C] | | components [F] | |
| | | | Content | | Content | | Content | | Content |
| | Composition | | (parts by | | (parts by | | (parts by | | (parts by |
| | (J) | Type | mass) | Type | mass) | Type | mass) | Type | mass) |
| Example 1-1 | J-1 | A-1 | 10 | B-1 | 0.3 | C-3 | 90 | — | — |
| Example 1-2 | J-2 | A-2 | 10 | B-1 | 0.3 | C-1 | 90 | — | — |
| Example 1-3 | J-3 | A-3 | 10 | B-1 | 0.3 | C-1 | 90 | — | — |
| Example 1-4 | J-4 | A-4 | 10 | B-1 | 0.3 | C-1 | 90 | F-1 | 0.005 |
| Example 1-5 | J-5 | A-5 | 10 | B-1 | 0.3 | C-1 | 90 | F-1 | 0.005 |
| Example 1-6 | J-6 | A-6 | 10 | B-1 | 0.3 | C-1 | 90 | F-1 | 0.005 |
| Example 1-7 | J-7 | A-7 | 10 | B-1 | 0.3 | C-1 | 90 | F-1 | 0.005 |
| Example 1-8 | J-8 | A-7 | 10 | B-2 | 0.3 | C-1 | 90 | F-1 | 0.005 |
| Example 1-9 | J-9 | A-7 | 10 | B-3 | 0.3 | C-1/C-3 | 80/10 | F-1 | 0.005 |
| Example 1-10 | J-10 | A-7 | 10 | B-4 | 0.3 | C-1/C-3 | 80/10 | F-1 | 0.005 |
| Example 1-11 | J-11 | A-7 | 10 | B-5 | 0.3 | C-1 | 90 | F-1 | 0.005 |
| Example 1-12 | J-12 | A-7 | 10 | B-6 | 0.3 | C-1 | 90 | F-1 | 0.005 |
| Example 1-13 | J-13 | A-7 | 10 | B-7 | 0.3 | C-1 | 90 | F-1 | 0.005 |
| Example 1-14 | J-14 | A-7 | 10 | B-8 | 0.3 | C-1 | 90 | F-1 | 0.005 |
| Example 1-15 | J-15 | A-7 | 10 | B-9 | 0.3 | C-1 | 90 | F-1 | 0.005 |
| Example 1-16 | J-16 | A-7 | 10 | B-10 | 0.3 | C-1 | 90 | F-1 | 0.005 |
| Example 1-17 | J-17 | A-7 | 10 | B-11 | 0.3 | C-1/C-3 | 80/10 | F-1 | 0.005 |
| Example 1-18 | J-18 | A-7 | 10 | B-12 | 0.3 | C-1/C-3 | 80/10 | F-1 | 0.005 |
| Example 1-19 | J-19 | A-7 | 10 | B-13 | 0.3 | C-1/C-3 | 80/10 | F-1 | 0.005 |
| Example 1-20 | J-20 | A-8 | 10 | B-1 | 0.3 | C-1 | 90 | — | — |
| Example 1-21 | J-21 | A-9 | 10 | B-1 | 0.3 | C-1 | 90 | F-1 | 0.005 |
| Example 1-22 | J-22 | A-9 | 10 | B-1 | 0.05 | C-1 | 90 | F-1 | 0.005 |
| Example 1-23 | J-23 | A-9 | 10 | B-1 | 0.1 | C-1 | 90 | F-1 | 0.005 |
| Example 1-24 | J-24 | A-9 | 10 | B-1 | 0.5 | C-1 | 90 | F-1 | 0.005 |
| Example 1-25 | J-25 | A-9 | 10 | B-1 | 0.7 | C-1 | 90 | F-1 | 0.005 |
| Example 1-26 | J-26 | A-9 | 10 | B-1 | 1 | C-1 | 90 | F-1 | 0.005 |
| Example 1-27 | J-27 | A-9 | 10 | B-1 | 1 | C-1/C-3 | 80/10 | F-1 | 0.005 |
| Example 1-28 | J-28 | A-9 | 10 | B-1 | 1 | C-1/C-3/C-4 | 65/10/15 | F-1 | 0.005 |
| Example 1-29 | J-29 | A-9 | 10 | B-1 | 1 | C-1/C-3/C-6 | 50/10/32 | F-1 | 0.005 |
| Example 1-30 | J-30 | A-9 | 10 | B-1 | 2 | C-1 | 90 | F-1 | 0.005 |
| Example 1-31 | J-31 | A-9 | 10 | B-1 | 2 | C-1/C-3 | 80/10 | F-1 | 0.005 |
| Example 1-32 | J-32 | A-9 | 10 | B-1 | 2 | C-1/C-3/C-4 | 65/10/15 | F-1 | 0.005 |
| Example 1-33 | J-33 | A-9 | 10 | B-1 | 2 | C-1/C-3/C-6 | 50/10/32 | F-1 | 0.005 |
| Example 1-34 | J-34 | A-9 | 10 | B-1 | 0.3 | C-1 | 90 | F-1/F-2 | 0.005/0.05 |
| Example 1-35 | J-35 | A-9 | 10 | B-1 | 0.3 | C-1 | 90 | F-1/F-3 | 0.005/0.05 |
| Example 1-36 | J-36 | A-9 | 10 | B-1 | 0.3 | C-1 | 90 | F-1/F-4 | 0.005/0.05 |
| Example 1-37 | J-37 | A-9 | 10 | B-1 | 0.3 | C-1 | 90 | F-1/F-5 | 0.005/0.05 |
| Example 1-38 | J-38 | A-9 | 10 | B-1 | 0.3 | C-1 | 90 | F-1/F-6 | 0.005/0.05 |
| Example 1-39 | J-39 | A-9 | 10 | B-1 | 0.3 | C-1/C-4 | 72/18 | F-1 | 0.005 |
| Example 1-40 | J-40 | A-9 | 10 | B-1 | 0.3 | C-1/C-6 | 54/36 | F-1 | 0.005 |
| Example 1-41 | J-41 | A-10 | 10 | B-1 | 0.3 | C-1 | 90 | F-1 | 0.005 |
| Example 1-42 | J-42 | A-11 | 10 | B-1 | 0.3 | C-1 | 90 | — | — |
| Example 1-43 | J-43 | A-12 | 10 | B-1 | 0.3 | C-1 | 90 | — | — |
| Example 1-44 | J-44 | A-13 | 10 | B-1 | 0.3 | C-2 | 90 | — | — |
| Example 1-45 | J-45 | A-14 | 10 | B-1 | 0.3 | C-5 | 90 | — | — |
| Example 1-46 | J-46 | A-15 | 10 | B-1 | 0.3 | C-2 | 90 | — | — |
| Example 1-47 | J-47 | A-16 | 10 | B-1 | 0.3 | C-1 | 90 | — | — |
| Comparative | j-1 | A-9 | 10 | — | — | C-1 | 90 | F-1 | 0.005 |
| Example 1-1 | | | | | | | | | |

### <Evaluation>

In Examples 2-1 to 2-47 and Comparative Example 2-1, a composition prepared in <Preparation of composition> described above and a substrate with a film obtained in <Formation of film> described below were evaluated for embeddability and etching resistance by the methods described below. The evaluation results are shown in the following Table 3.

### [Embeddability]

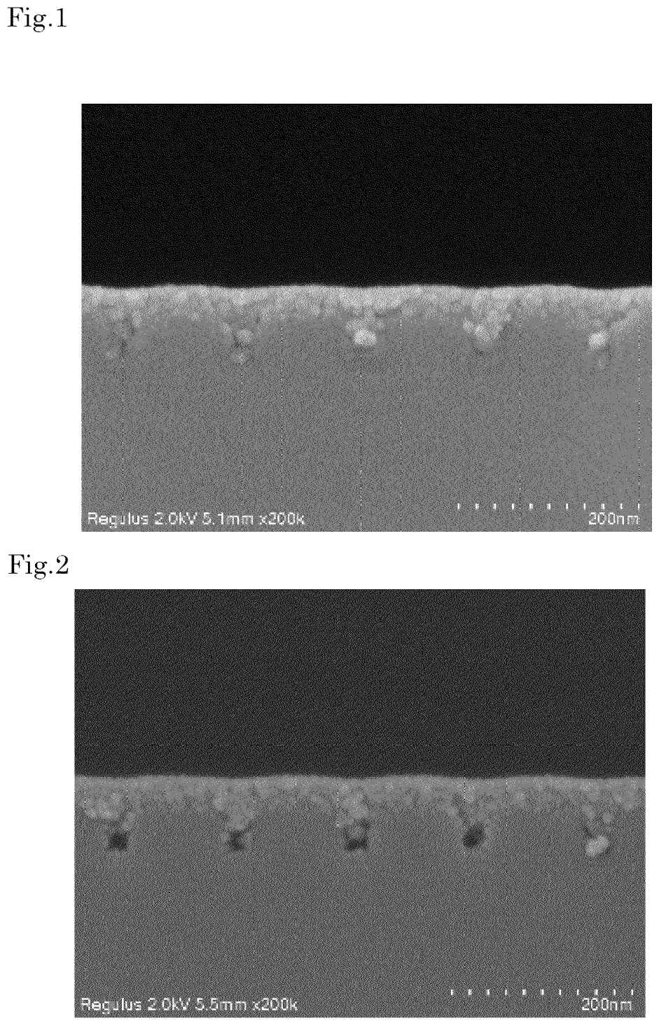

The composition was applied to a substrate with a trench pattern formed thereon having a depth of 50 nm and a width of 30 nm by spin coating using a spin coater (“LITHIUS Pro Z” available from Tokyo Electron Limited). The rotation condition of the spin coater was set such that a film-attached substrate with a film having an average thickness of 60 nm formed thereon could be obtained. Next, in the air atmosphere, the resultant was heated at 450° C. for 60 seconds and then cooled at 23° C. for 60 seconds. The sectional shape of the substrate was observed (200,000 magnifications) with a scanning electron microscope (“S-4800” manufactured by Hitachi High-Technologies Corporation), and embeddability was evaluated. FIG. 1 is an electron micrograph taken when a trench pattern is embedded using the composition of Example 1-1. FIG. 2 is an electron micrograph taken when a trench pattern is embedded using the composition of Comparative Example 1-1. The embeddability was evaluated as “A” (good) when the film was embedded to the bottom of the space pattern of the substrate (namely, when there was no void), and evaluated as “B” (poor) when the film was not embedded to the bottom of the space pattern (namely, when there was a void).

### <Formation of Film>

A composition prepared as described above was applied to a silicon wafer (substrate) by spin coating using a spin coater (“LITHIUS Pro Z” available from Tokyo Electron Limited). Next, in the air atmosphere, the resultant was heated at 450° C. for 60 seconds and then cooled at 23° C. for 600 seconds, thereby affording a film-attached substrate with a film having an average thickness of 60 nm formed thereon.

### [Etching Resistance]

Using an etching apparatus (“TACTRAS” manufactured by Tokyo Electron Limited), the film of the film-attached substrate was processed under the conditions of CF₄/Ar=110/440 sccm, PRESS.=30 MT, HF RF (high-frequency power for plasma generation)=500 W, LF RF (high-frequency power for bias)=3000 W, DCS=−150 V, RDC (gas center flow ratio)=50%, and 30 seconds, and the etching rate (nm/min) was calculated from the average thickness of the film before and after the processing. Next, taking the etching rate of Comparative Example 2-1 as a standard, the ratio of the etching rate calculated above to that of Comparative Example 2-1 was calculated, and this ratio was taken as a measure of etching resistance. The etching resistance was evaluated as “A” (extremely good) when the ratio was less than 0.98, “B” (good) when the ratio was 0.98 or more and less than 1.00, and “C” (poor) when the ratio was 1.00 or more. “-” in the following Table 3 indicates that it is an evaluation standard of etching resistance.

TABLE 3

| | Composition | Embeddability | Etching resistance |
|---|---|---|---|
| Example 2-1 | J-1 | A | A |
| Example 2-2 | J-2 | A | A |
| Example 2-3 | J-3 | A | A |
| Example 2-4 | J-4 | A | A |
| Example 2-5 | J-5 | A | A |
| Example 2-6 | J-6 | A | A |
| Example 2-7 | J-7 | A | A |
| Example 2-8 | J-8 | A | A |
| Example 2-9 | J-9 | A | A |
| Example 2-10 | J-10 | A | A |
| Example 2-11 | J-11 | A | A |
| Example 2-12 | J-12 | A | A |
| Example 2-13 | J-13 | A | A |
| Example 2-14 | J-14 | A | A |
| Example 2-15 | J-15 | A | A |
| Example 2-16 | J-16 | A | A |
| Example 2-17 | J-17 | A | A |
| Example 2-18 | J-18 | A | A |
| Example 2-19 | J-19 | A | A |
| Example 2-20 | J-20 | A | A |
| Example 2-21 | J-21 | A | A |
| Example 2-22 | J-22 | A | A |
| Example 2-23 | J-23 | A | A |
| Example 2-24 | J-24 | A | A |
| Example 2-25 | J-25 | A | A |
| Example 2-26 | J-26 | A | A |
| Example 2-27 | J-27 | A | A |
| Example 2-28 | J-28 | A | A |
| Example 2-29 | J-29 | A | A |
| Example 2-30 | J-30 | A | A |
| Example 2-31 | J-31 | A | A |
| Example 2-32 | J-32 | A | A |
| Example 2-33 | J-33 | A | A |
| Example 2-34 | J-34 | A | A |
| Example 2-35 | J-35 | A | A |
| Example 2-36 | J-36 | A | A |
| Example 2-37 | J-37 | A | A |
| Example 2-38 | J-38 | A | A |
| Example 2-39 | J-39 | A | A |
| Example 2-40 | J-40 | A | A |
| Example 2-41 | J-41 | A | A |
| Example 2-42 | J-42 | A | A |
| Example 2-43 | J-43 | A | A |
| Example 2-44 | J-44 | A | A |
| Example 2-45 | J-45 | A | A |
| Example 2-46 | J-46 | A | A |
| Example 2-47 | J-47 | A | A |
| Comparative | j-1 | B | — |
| Example 2-1 | | | |

As can be seen from the results in Table 3, the compositions of Examples and the resist underlayer films formed from the compositions were superior in embeddability and etching resistance to Comparative Example.

By the method for manufacturing a semiconductor substrate of the present disclosure, since a resist underlayer film superior in etching resistance and embeddability is formed, a well patterned semiconductor substrate can be obtained. When the composition for film formation of the present disclosure is used, a film superior in etching resistance and embeddability can be formed. Therefore, these can suitably be used for, for example, manufacturing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising
applying a composition for film formation to a substrate,
the composition for film formation comprising:
a metal compound;
an aromatic compound comprising an aromatic hydrocarbon ring structure and a partial structure represented by formula (1); and
a solvent, and
the aromatic hydrocarbon ring structure having 6 or more carbon atoms, 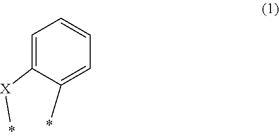
in the formula (1), X is a group represented by formula (i), (ii), (iii) or (iv); and * are bonding sites with two adjacent carbon atoms constituting the aromatic hydrocarbon ring structure, 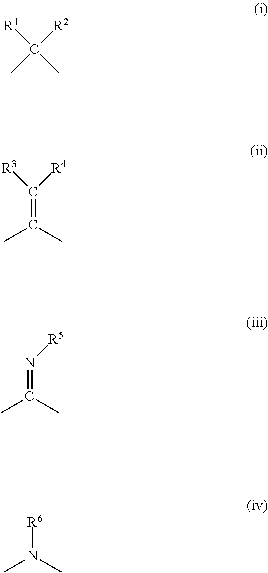
in the formula (i), R¹ is a hydrogen atom or a monovalent organic group having 1 to 20 carbon atoms, and R² is a monovalent organic group having 1 to 20 carbon atoms;
in the formula (ii), R³ is a hydrogen atom or a monovalent organic group having 1 to 20 carbon atoms, and R⁴ is a monovalent organic group having 1 to 20 carbon atoms;
in the formula (iii), R⁵ is a monovalent organic group having 1 to 20 carbon atoms; and
in the formula (iv), R⁶ is a monovalent organic group having 1 to 20 carbon atoms.

2. The method according to claim 1, wherein a metal atom contained in the metal compound belongs to Groups 3 to 16 of a periodic table.

3. The method according to claim 1, wherein a metal atom contained in the metal compound belongs to Group 4 of a periodic table.

4. The method according to claim 1, wherein the aromatic compound comprises at least one group selected from the group consisting of a group represented by formula (2-1) and a group represented by formula (2-2), 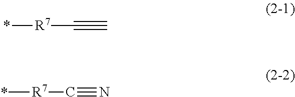
in the formulas (2-1) and (2-2), R⁷ is independently at each occurrence a substituted or unsubstituted divalent hydrocarbon group having 1 to 20 carbon atoms or a single bond; and * is a bond with a carbon atom in the aromatic compound.

5. The method according to claim 1, wherein the aromatic compound has no oxygen atom.

6. The method according to claim 1, wherein an amount of the aromatic compound is 0.1 parts by mass or more and 50 parts by mass or less based on 100 parts by mass of the metal compound.

7. The method according to claim 1, wherein the substrate has a pattern.

8. A composition for film formation, the composition comprising:
a metal compound;
an aromatic compound comprising an aromatic hydrocarbon ring structure and a partial structure represented by formula (1); and
a solvent, and
the aromatic hydrocarbon ring structure having 6 or more carbon atoms, 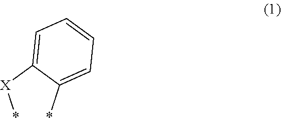
in the formula (1), X is a group represented by formula (i), (ii), (iii) or (iv); and * are bonding sites with two adjacent carbon atoms constituting the aromatic hydrocarbon ring structure, 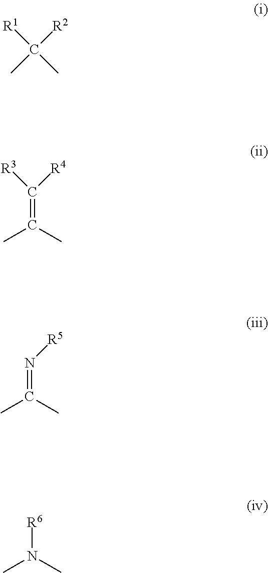
in the formula (i), R¹ is a hydrogen atom or a monovalent organic group having 1 to 20 carbon atoms, and R² is a monovalent organic group having 1 to 20 carbon atoms;
in the formula (ii), R³ is a hydrogen atom or a monovalent organic group having 1 to 20 carbon atoms, and R⁴ is a monovalent organic group having 1 to 20 carbon atoms;
in the formula (iii), R⁵ is a monovalent organic group having 1 to 20 carbon atoms; and
in the formula (iv), R⁶ is a monovalent organic group having 1 to 20 carbon atoms.

9. The composition according to claim 8, wherein the composition is suitable for pattern embedding of a substrate having a pattern.

10. The composition according to claim 8, wherein a metal atom contained in the metal compound belongs to Groups 3 to 16 of a periodic table.

11. The composition according to claim 8, wherein a metal atom contained in the metal compound belongs to Group 4 of a periodic table.

12. The composition according to claim 8, wherein the aromatic compound comprises at least one group selected from the group consisting of a group represented by formula (2-1) and a group represented by formula (2-2), 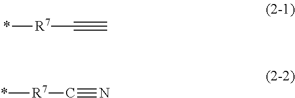
in the formulas (2-1) and (2-2), R⁷ is independently at each occurrence a substituted or unsubstituted divalent hydrocarbon group having 1 to 20 carbon atoms or a single bond; and * is a bond with a carbon atom in the aromatic compound.

13. The composition according to claim 8, wherein the aromatic compound has no oxygen atom.

14. The composition according to claim 8, wherein an amount of the aromatic compound is 0.1 parts by mass or more and 50 parts by mass or less based on 100 parts by mass of the metal compound.
